(19) United States
(12) Patent Application Publication
(10) Pub. No.: US 2015/0084204 A1
(43) Pub. Date: Mar. 26, 2015

(54) SEMICONDUCTOR DEVICE AND METHOD OF FABRICATING THE SAME

(71) Applicants: Jang-Gn Yun, Hwaseong-si (KR); Jaesun Yun, Anyang-si (KR); Hoosung Cho, Yongin-si (KR)

(72) Inventors: Jang-Gn Yun, Hwaseong-si (KR); Jaesun Yun, Anyang-si (KR); Hoosung Cho, Yongin-si (KR)

(21) Appl. No.: 14/313,031

(22) Filed: Jun. 24, 2014

(30) Foreign Application Priority Data
Sep. 25, 2013 (KR) 10-2013-00114017

(51) Int. Cl. H01L 27/112; H01L 21/768; H01L 23/48

(52) U.S. Cl. CPC H01L 27/11286; H01L 23/481; H01L 21/76895
USPC 257/773; 438/618

(57) ABSTRACT

Provided are a semiconductor device and a method of fabricating the same. The device may include a substrate including a cell array region and a peripheral circuit region, stacks on the cell array region of the substrate, the stacks having a first height and extending along a direction, a common source structure disposed between adjacent ones of the stacks, a peripheral logic structure disposed on the peripheral circuit region of the substrate and having a second height smaller than the first height, a plurality of upper interconnection lines disposed on the peripheral logic structure and extending parallel to each other, and a interconnection structure disposed between the peripheral logic structure and the upper interconnection lines, when viewed in vertical section, and electrically connected to at least two of the upper interconnection lines.

### REFERENCE TO PRIORITY APPLICATION

This patent application claims priority to Korean Patent Application No. 10-2013-00114017, filed Sep. 25, 2013, the contents of which are hereby incorporated herein by reference.

### FIELD

Example embodiments of the inventive concept relate to a semiconductor device and a method of fabricating the same, and in particular, to a three-dimensional semiconductor device, whose reliability and density are improved, and a method of fabricating the same.

### BACKGROUND

The continued development of highly integrated semiconductor devices is spurred in part by consumer demand for low-cost, superior performance products. Indeed, particularly in the case of semiconductor devices, increased device integration is a major factor in achieving price points satisfying market demands. Conventionally, semiconductor memory devices include planar or two-dimensional (2D) memory cell arrays (i.e., memory cell arrays having memory cells laid-out in a two-dimensional plane). Further integration of such devices is becoming more difficult and costly as patterning technologies approach practical limits. At the very least, prohibitively expensive process equipment would be needed to achieve major advances in 2D memory cell array device integration.

As a result, three-dimensional (3D) semiconductor memory devices have been proposed in which the memory cells of the memory cell array are arranged in three dimensions. However, there are significant manufacturing obstacles in achieving low-cost, mass-production of 3D semiconductor memory devices, particularly in the mass-fabrication of 3D devices that maintain or exceed the operational reliability of their 2D counterparts.

### SUMMARY

Example embodiments of the inventive concept provide a semiconductor device having improved reliability and density. Other example embodiments of the inventive concept provide a method of fabricating a semiconductor device with improved reliability and density.

An integrated circuit memory device according to embodiments of the invention includes a plurality of stacks of a first height on a cell array region of a substrate, which contains the cell array region and a peripheral circuit region therein. A common source structure is provided, which extends between adjacent ones of the plurality of stacks. A logic structure of a second height less than the first height is also provided. This logic structure extends on the peripheral circuit region of the substrate. A plurality of upper interconnection lines are provided, which extend on the logic structure. An interconnection structure is also provided, which extends between the logic structure and the plurality of upper interconnection lines. This interconnection structure, which is electrically coupled to at least two of the plurality of upper interconnection lines, has a top surface positioned between a top surface of the common source structure and bottom surfaces of the plurality of upper interconnection lines.

According to additional embodiments of the invention, a bottom surface of the interconnection structure is positioned between top and bottom surfaces of the common source structure. In addition, a top width of the interconnection structure may be smaller than a width of the common source structure. In some additional embodiments of the invention, the interconnection structure may include a first portion having a first top width smaller than a top width of the common source structure and a second portion having a second top width greater than a top width of the common source structure. In addition, a vertical length of the first portion of the interconnection structure may be smaller than a vertical length of the second portion of the interconnection structure. In still further embodiments of the invention, the interconnection structure may include a wiring portion and an insulating spacer. The wiring portion, which may be provided on the peripheral circuit region, may have a bottom surface spaced apart from a top surface of the substrate and a side surface disposed at a non-orthogonal angle relative to the top surface of the substrate. The insulating spacer may enclose the side and bottom surfaces of the wiring portion.

According to additional embodiments of the inventive concept, a semiconductor device may include a substrate including a cell array region and a peripheral circuit region, stacks on the cell array region of the substrate, the stacks having a first height and extending along a direction, a common source structure disposed between adjacent ones of the stacks, a peripheral logic structure disposed on the peripheral circuit region of the substrate and having a second height smaller than the first height, a plurality of upper interconnection lines disposed on the peripheral logic structure and extending parallel to each other, and a interconnection structure disposed between the peripheral logic structure and the upper interconnection lines, when viewed in vertical section, and electrically connected to at least two of the upper interconnection lines. A top surface of the interconnection structure may be positioned between a top surface of the common source structure and bottom surfaces of the upper interconnection lines, when viewed in vertical section.

According to example embodiments of the inventive concept, a method of fabricating a semiconductor device may include providing a substrate with a cell array region and a peripheral circuit region, forming a plurality of stacks on the cell array region of the substrate, the stacks extending along a direction and defining a cell trench exposing the substrate, forming an insulating gap-fill layer on the peripheral circuit region of the substrate to include a first peripheral trench, whose bottom surface is spaced apart from a top surface of the substrate and whose top width is smaller than a top width of the cell trench, forming an insulating sidewall spacer in the cell trench and a first insulating spacer in the first peripheral trench, the insulating sidewall spacer exposing the substrate and the first insulating spacer covering side and bottom surfaces of the first peripheral trench, and forming a common source line filling the cell trench provided with the insulating sidewall spacer and a conductive line filling the first peripheral trench provided with the first insulating spacer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor device according to example embodiments of the inventive concept.

FIG. 2 is a sectional view taken along lines I-I′ and II-II′ of FIG. 1.

FIG. 3 is a perspective view illustrating a semiconductor device according to example embodiments of the inventive concept.

FIG. 4 is a sectional view illustrating a semiconductor device according to a modification of example embodiments of the inventive concept.

FIG. 5 is a plan view illustrating a semiconductor device according to other example embodiments of the inventive concept.

FIG. 6 is a sectional view taken along lines III-III′ and IV-IV′ of FIG. 5.

FIGS. 7 through 10 are sectional views taken along lines I-I′ and II-II′ of FIG. 1 to illustrate a method of fabricating a semiconductor device according to example embodiments of the inventive concept.

FIG. 11 is a plan view schematically illustrating a structure of a semiconductor memory device according to example embodiments of the inventive concept.

FIG. 12 is a block diagram illustrating a semiconductor memory device according to example embodiments of the inventive concept.

FIG. 13 is a circuit diagram schematically illustrating a cell array region of a semiconductor memory device, according to example embodiments of the inventive concept.

FIG. 14 is a perspective view illustrating a cell array region of a semiconductor memory device according to example embodiments of the inventive concept.

FIG. 15 is a plan view illustrating a semiconductor memory device according to example embodiments of the inventive concept.

FIG. 16 is a sectional view taken along lines V-V′ and VI-VI′ of FIG. 15.

FIG. 17 is a sectional view taken along lines V-V′ and VI-VI′ of FIG. 15.

FIG. 18 is a plan view of a semiconductor memory device according to still other example embodiments of the inventive concept.

FIG. 19 is a sectional view taken along lines VII-VII′ and VIII-VIII′ of FIG. 18 to illustrate a semiconductor memory device according to still other example embodiments of the inventive concept.

FIG. 20 is a sectional view illustrating a semiconductor memory device according to even other example embodiments of the inventive concept.

FIGS. 21 through 30 are sectional views taken along lines I-I′, II-II′, and III-III′ of FIG. 15 to illustrate a method of fabricating a semiconductor memory device according to example embodiments of the inventive concept.

FIGS. 31A and 32A are plan views of semiconductor devices according to further embodiments of the inventive concept.

FIGS. 31B and 32B are sectional views taken along lines IX-IX′ of FIGS. 31A and 32A, respectively, to illustrate the semiconductor devices according to further embodiments of the inventive concept.

FIG. 33 is a plan view of a semiconductor memory device according to still further embodiments of the inventive concept.

FIG. 34 is a sectional view taken along line X-X′ of FIG. 33 to illustrate the semiconductor device according to still further embodiments of the inventive concept.

FIG. 35 is a plan view of a semiconductor memory device according to even further embodiments of the inventive concept.

FIG. 36 is a sectional view taken along line XI-XI′ of FIG. 35 to illustrate the semiconductor device according to even further embodiments of the inventive concept.

FIG. 37 is a schematic block diagram illustrating an example of memory systems including a semiconductor memory device according to example embodiments of the inventive concept.

FIG. 38 is a schematic block diagram illustrating an example of memory cards including a semiconductor memory device according to example embodiments of the inventive concept.

FIG. 39 is a schematic block diagram illustrating an example of information processing systems including a semiconductor memory device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

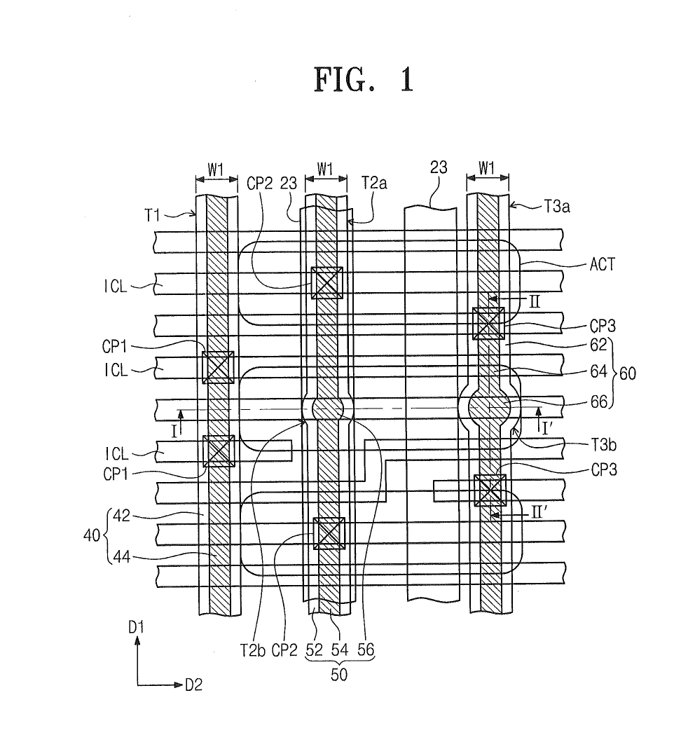

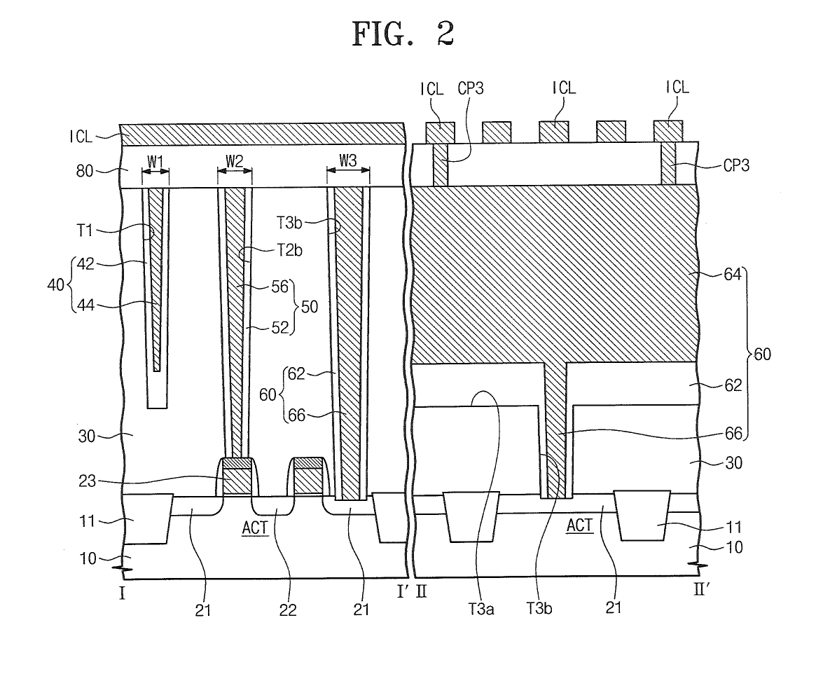

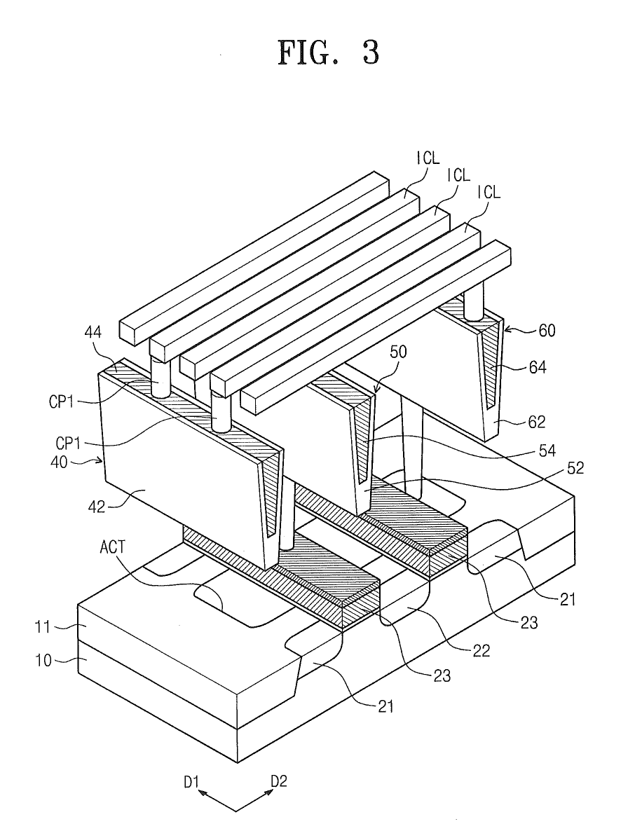

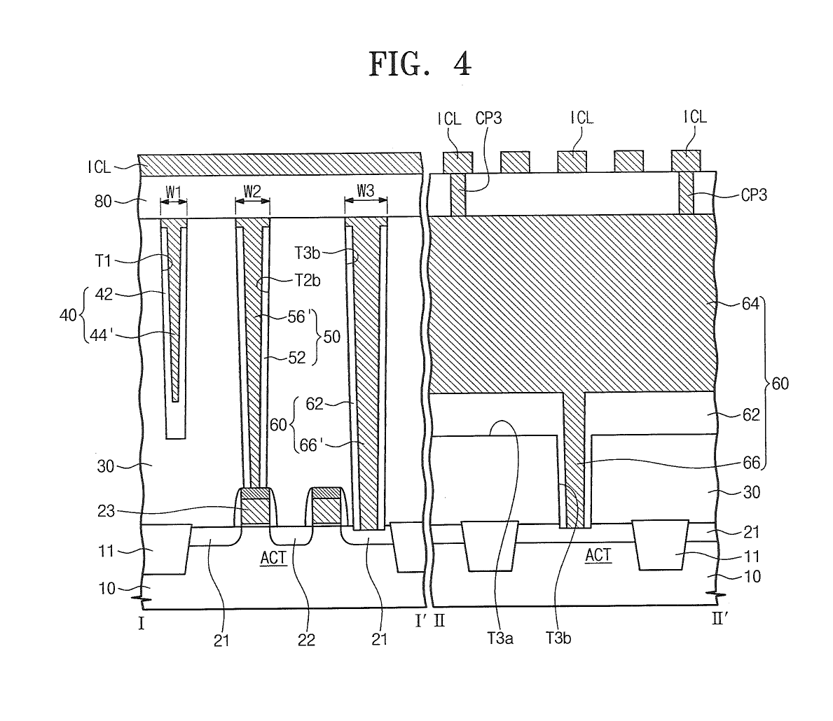

FIG. 1 is a plan view illustrating a semiconductor device according to example embodiments of the inventive concept, and FIG. 2 is a sectional view taken along lines I-I′ and II-II′ of FIG. 1. FIG. 3 is a perspective view illustrating a semiconductor device according to example embodiments of the inventive concept. FIG. 4 is a sectional view illustrating a semiconductor device according to a modification of example embodiments of the inventive concept. Referring to FIGS. 1, 2, and 3, a device isolation layer 11 may be provided on a semiconductor substrate 10 to define active regions ACT. The semiconductor substrate 10 may be a bulk silicon wafer, a silicon-on-insulator (SOI) wafer, a germanium wafer, a germanium-on-insulator (GOI) wafer, a silicon-germanium wafer, or a substrate including an epitaxial layer formed by a selective epitaxial growth (SEG) process. The active regions ACT defined by the device isolation layer 11 may be portions of the semiconductor substrate 10, in which a well region (not shown) doped with n- or p-type impurities may be provided. Gate electrodes 23 may be provided on the semiconductor substrate 10 with a gate insulating layer interposed therebetween. The gate electrodes 23 may extend to cross the active regions ACT (for example, parallel to a first direction D1).

The gate electrodes 23 may be formed of a doped polysilicon layer or a conductive material, whose work-function is higher than that of the doped polysilicon layer. For example, the gate electrodes 23 may include at least one of metallic materials (e.g., tungsten or molybdenum), conductive metal nitride materials (e.g., titanium nitride, tantalum nitride, tungsten nitride, and titanium-aluminum-nitride), or metal silicides (e.g., tungsten silicide). The gate insulating layer may include oxide, nitride, oxynitride, and/or high-k materials including insulating metal oxides (e.g., hafnium oxide or aluminum oxide).

Source and drain impurity regions 21 and 22 may be formed in portions of the active regions ACT positioned at both sides of the gate electrodes 23. The source and drain impurity regions 21 and 22 may be formed to have a different conductivity type from that of the active region ACT. A first interlayered insulating layer 30 may be thickly provided on the semiconductor substrate 10 provided with the gate electrodes 23. The first interlayered insulating layer 30 may include an insulating layer or a plurality of stacked insulating layers.

In example embodiments, a first interconnection structure 40, a second interconnection structure 50 and a third interconnection structure 60 may be provided in the first interlayered insulating layer 30. The first to third interconnection structures 40, 50, and 60 may extend along a first direction D1 parallel to the gate electrodes 23. The first to third interconnection structures 40, 50, and 60 may have vertical heights different from each other, and the first to third interconnection structures 40, 50, and 60 may have top surfaces that are coplanar with each other. In example embodiments, the first interconnection structure 40 may be provided over the device isolation layer 11 to be spaced apart from the top surface of the device isolation layer 11, and the second and third interconnection structures 50 and 60 may be disposed to cross the active regions ACT.

As shown by FIG. 2, the first interconnection structure 40 may be provided in a first trench T1, which may be formed in the first interlayered insulating layer 30. The first interconnection structure 40 may include a first insulating spacer 42 and a first wiring portion 44. For example, the first trench T1 may extend along the first direction D1 with a uniform top width of W1. The first trench T1 may have a bottom surface spaced apart from a top surface of the semiconductor substrate 10 and a sidewall at an angle to the top surface of the semiconductor substrate 10. In example embodiments, the vertical length of the first trench T1 may be changed depending on the top width W1 of the first trench T1.

The first insulating spacer 42 may cover an inner wall of the first trench T1 conformally. Alternatively, in the case where the first trench T1 has a tapered shape, a thickness of the first insulating spacer 42 may be larger on the bottom surface of the first trench T1 than on the sidewall of the first trench T1. For example, the thickness of the first insulating spacer 42 on the sidewall of the first trench T1 may be smaller than about ½ of the top width W1 of the first trench T1, and the thickness of the first insulating spacer 42 on the bottom surface of the first trench T1 may be larger than about 2 times the top width W1 of the first trench T1. The first wiring portion 44 may be formed of a conductive material. Further, the first wiring portion 44 may be spaced apart from the top surface of the semiconductor substrate 10 and extend along the first direction D1.

In example embodiments, the second interconnection structure 50 may be provided in a second trench, which may be formed in the first interlayered insulating layer 30. The second interconnection structure 50 may include a second insulating spacer 52, a second wiring portion 54, and a second contact portion 56. The second trench may include first portions T2a and a second portion T2b between the first portions T2a. The first portions T2a may have a substantially uniform top width (e.g., the first top width W1), and the second portion T2b may have a second top width W2 larger than the first top width W1. In other words, the first and second trenches T1 and T2a may have substantially the same top width (e.g., the first top width W1). Further, the vertical length of the second trench may be changed depending on the top width thereof. Similar to the first trench T1, the bottom surfaces of the first portions T2a of the second trench may be spaced apart from the top surface of the semiconductor substrate 10, and the second portion T2b of the second trench may be formed to penetrate a portion of the first interlayered insulating layer 30. Accordingly, the second portion T2b of the second trench may expose locally the top surface of the gate electrode. Further, the second trench may have a slanted sidewall and the second portion T2b may have a round sidewall, in a plan view. In example embodiments, a position of the second portion T2b exposing a top surface of the gate electrode 23 may be changed depending on a designed structure of a semiconductor device.

The second insulating spacer 52 may be formed in the second trench. In example embodiments, the second insulating spacer 52 may cover side and bottom surfaces of the first portions T2a of the second trench and cover a side surface of the second portion T2b of the second trench. In other words, the second insulating spacer 52 may expose locally the top surface of the gate electrode 23 below the second portion T2b. Further, the second insulating spacer 52 may be formed to be thicker on the bottom surface of the first portions T2a than on the side surfaces of the second trench.

The second wiring portion 54 and the second contact portion 56 may be provided in the first and second portions, respectively, of the second trench provided with the second insulating spacer 52. The second wiring portion 54 and the second contact portion 56 may be formed of the same conductive material. Here, the second wiring portion 54 and the second contact portion 56 may have different vertical lengths from each other. The second wiring portion 54 and the first wiring portion 44 may have substantially the same top width, the second contact portion 56 may have a top width larger than that of the second wiring portion 54. The second wiring portion 54 may be spaced apart from the top surface of the semiconductor substrate 10. Further, the second wiring portion 54 may extend along the first direction D1, and the second contact portion 56 may be in contact with a portion of the gate electrode 23. Accordingly, the second wiring portion 54 and the second contact portion 56 may be electrically connected to the gate electrode 23.

In example embodiments, the third interconnection structure 60 may be provided in a third trench, which may be formed in the first interlayered insulating layer 30. The third interconnection structure 60 may include a third insulating spacer 62, a third wiring portion 64, and a third contact portion 66. Similar to the second trench, the third trench may include the first portions T3a having substantially a uniform top width (e.g., the first top width W1) and the second portion T3b disposed between the first portions T3a to have a third top width W3 larger than the first top width W1. Further, the vertical length of the first portions T3a of the third trench may be changed depending on the first top width W1 of the third trench. In example embodiments, the first top width W1 of the third trench may be substantially the same as the top width W1 of the first trench T1, and the third top width W3 of the third trench may be larger than the second top width W2 of the second trench. Accordingly, the second portion T3b of the third trench may expose locally the source or drain impurity region 21 or 22. Further, the third trench may have a slanted sidewall, and the second portion T3b of the third trench may have a round sidewall. In example embodiments, a position of the second portion T3b exposing the top surface of the source or drain impurity region 21 or 22 may be changed depending on a designed structure of a semiconductor device.

The third insulating spacer 62 may be formed in the third trench. In example embodiments, the third insulating spacer 62 may cover side and bottom surfaces of the first portions T3a of the third trench and cover a side surface of the second portion T3b of the third trench. In other words, the third insulating spacer 62 may expose locally the source or drain impurity region 21 or 22 below the second portion T3b of the third trench. Further, the third insulating spacer 62 may be formed to be thicker on the bottom surface of the first portions T3a of the third trench than on the side surfaces of the third trench.

The third wiring portion 64 and the third contact portion 66 may be disposed in the third trench provided with the third insulating spacer 62. For example, the third wiring portion 64 may be disposed in the first portions T3a of the third trench to extend along the first direction D1. The third contact portion 66 may be disposed in the second portion T3b of the third trench. In certain embodiments, a vertical length of the third contact portion 66 may be larger than that of the second contact portion 56. A top width of the third wiring portion 64 may be substantially the same as that of the second wiring portion 54, and a top width of the third contact portion 66 may be larger than that of the second contact portion 56.

In example embodiments, a second interlayered insulating layer 80 may be disposed on the first interlayered insulating layer 30 to cover top surfaces of the first to third interconnection structures 40, 50, and 60. A plurality of upper interconnection lines ICL may be disposed on the second interlayered insulating layer 80 to extend along a second direction crossing the first to third interconnection structures 40, 50, and 60. When viewed in plan view, the upper interconnection lines ICL may include portions overlapped with the active regions ACT. The upper interconnection lines ICL may be arranged in a uniform space, and a pitch P of the upper interconnection lines ICL (that is, a sum of a line width of the upper interconnection line ICL and a space between two adjacent ones of the upper interconnection lines ICL) may be smaller than a width of the active region ACT.

When viewed in a vertical section, first to third contact plugs CP1, CP2, and CP3 may be disposed between the first to third interconnection structures 40, 50, and 60 and the upper interconnection lines ICL. Further, the first to third interconnection structures 40, 50, and 60 may be electrically connected to the upper interconnection lines ICL, which may be spaced apart from each other.

The first interconnection structure 40 may be electrically connected to at least one of the upper interconnection lines ICL via the first contact plugs CP1. For example, the first interconnection structure 40 may connect the upper interconnection lines ICL, which may be spaced apart from each other, electrically to each other using the first contact plugs CP1. The first contact plugs CP1 may be connected to the first wiring portion 44 of the first interconnection structure 40, and in certain embodiments, positions of the first contact plugs CP1 may be changed to connect the upper interconnection lines ICL, which may be spaced apart from each other, electrically to each other.

The second interconnection structure 50 may be electrically connected to at least one of the upper interconnection lines ICL via the second contact plugs CP2. The second contact plugs CP2 may be connected to the second wiring portion 54 and the second contact portion 56 of the second interconnection structure 50. Since the second interconnection structure 50 is connected to the gate electrode 23, at least one of the upper interconnection lines ICL may be connected in common to the gate electrode 23 via the second interconnection structure 50.

The third interconnection structure 60 may be electrically connected to at least one of the upper interconnection lines ICL via the third contact plugs CP2. The third contact plugs CP2 may be connected to the third wiring portion 64 and the third contact portion 66 of the third interconnection structure 60. Since the third interconnection structure 60 is connected to the source or drain impurity region 21 or 22, at least one of the upper interconnection lines ICL may be connected in common to the source or drain impurity region 21 or 22 via the third interconnection structure 60. Since the third interconnection structure 60 is disposed to cross the upper interconnection lines ICL, it is possible to connect easily the upper interconnection lines ICL to the source or drain impurity region 21 or 22, even in the case that, when viewed in plan view, the upper interconnection lines ICL are not overlapped with the source or drain impurity region 21 or 22.

According to the embodiment of FIG. 4, the first to third insulating spacers 42, 52, and 62 may have top surfaces that are lower than those of the first to third wiring portions 44, 54, and 64. For example, upper portions of the first to third wiring portions 44, 54, and 64 may cover the top surfaces of the first to third insulating spacers 42, 52, and 62. Further, the upper portions of the first to third wiring portions 44, 54, and 64 may be in direct contact with the first interlayered insulating layer 30. Accordingly, the first to third wiring portions 44, 54, and 64 may have increased top widths, and this makes it possible to improve a process margin in a process for forming the first to third contact plugs CP1, CP2, and CP3.

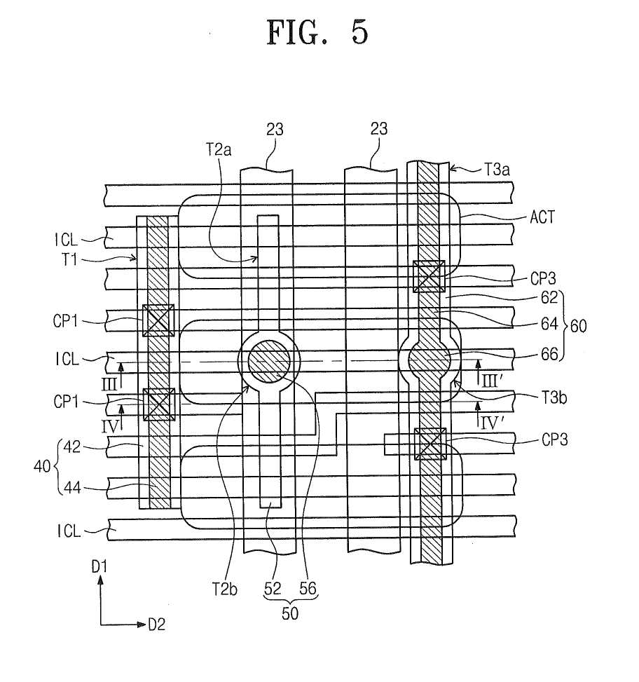

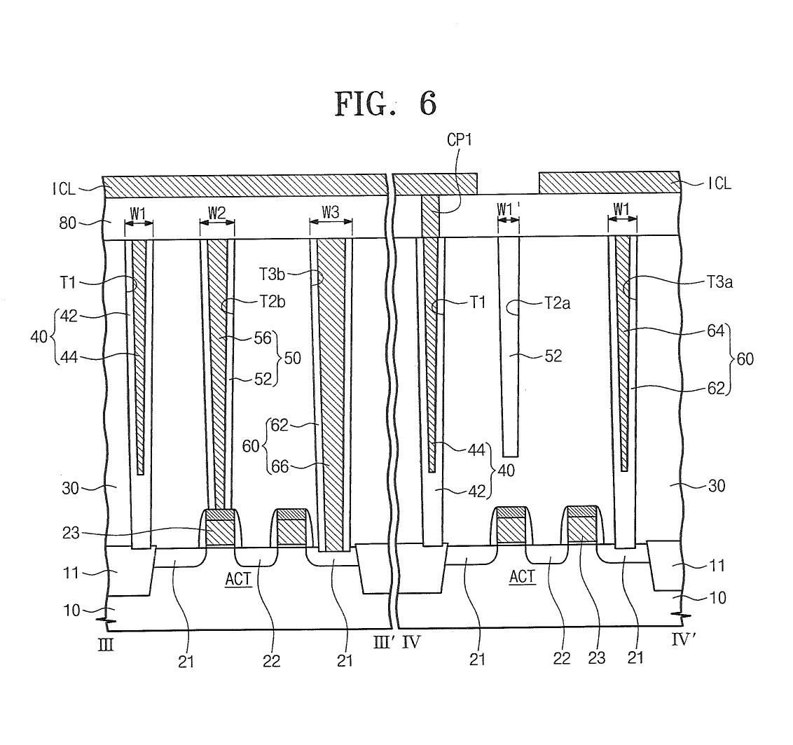

FIG. 5 is a plan view illustrating a semiconductor device according to other example embodiments of the inventive concept, and FIG. 6 is a sectional view taken along lines III-III′ and IV-IV′ of FIG. 5.

Referring to FIGS. 5 and 6, the active regions ACT may be defined in the semiconductor substrate 10 and the gate electrodes 23 may be provided to cross the active regions ACT. The first interlayered insulating layer 30 may be thickly disposed on the semiconductor substrate 10 provided with the gate electrodes 23, and the first to third interconnection structures 40, 50, and 60 may be provided in the first interlayered insulating layer 30, as described above.

As described above, the first interconnection structure 40 may be formed in the first trench T1 of the first interlayered insulating layer 30 and include the first insulating spacer 42 and the first wiring portion 44. In the present embodiment, the first insulating spacer 42 may be in contact with the top surface of the device isolation layer 11, and the first wiring portion 44 may be disposed spaced apart from the top surface of the device isolation layer 11. Furthermore, the first interconnection structure 40 may extend parallel to the gate electrodes 23 or along the first direction D1, and when measured in the first direction D1, a length of the first interconnection structure 40 may be shorter than that of the gate electrode 23.

The second interconnection structure 50 may be formed in the second trench of the first interlayered insulating layer 30 and include the second insulating spacer 52 and the second contact portion 56.

As described above, the second trench may include the first portions T2a having a substantially uniform top width (e.g., first top width W1′) and the second portion T2b, which is disposed between the first portions T2a to have the second top width W2 that is greater than the first top width W1′. Similar to the first trench T1, the bottom surfaces of the first portions T2a of the second trench may be spaced apart from the top surface of the semiconductor substrate 10, and the second portion T2b of the second trench may penetrate the first interlayered insulating layer 30. According to the present embodiment, the first top width W1′ of the second trench may be smaller than the top width W1 of the first trench T1, and the second top width W2 of the second trench may be larger than the top width W1 of the first trench T1. Further, the first portions T2a of the second trench may be completely filled with the second insulating spacer 52, and in the second portion T2b of the second trench, the second insulating spacer 52 may expose a portion of the gate electrode 23.

As described above, the third interconnection structure 60 may be provided in the third trench, which may be formed in the first interlayered insulating layer 30, and the third interconnection structure 60 may include the third insulating spacer 62, the third wiring portion 64, and the third contact portion 66. As described above, the third trench may include the first portions T3a having substantially a uniform top width (e.g., the first top width W1) and the second portion T3b, which may be disposed between the first portions T3a to have the third top width W3 larger than the first top width W1.

According to the present embodiment, in the first portions T3a of the third trench, the third insulating spacer 62 may extend to the top surface of the device isolation layer 11 or the source or drain impurity region 21 or 22. In addition, in the second portion T3b of the third trench, the third insulating spacer 62 may expose locally the top surface of the source or drain impurity region 21 or 22. Accordingly, the third wiring portion 64 formed in the first portions T3a of the third trench may be disposed spaced apart from the top surface of the semiconductor substrate 10, and the third contact portion 66 may be connected to the top surface of the source or drain impurity region 21 or 22.

The upper interconnection lines ICL may be provided on the first to third interconnection structures 40, 50, and 60 to extend parallel to a second direction D2, and the first interconnection structure 40 may connect electrically the upper interconnection lines spaced apart from each other by the first contact plugs CP1. Further, the third interconnection structure 60 may connect the upper interconnection lines ICL, which are spaced apart from each other, in common to the source or drain impurity region 21 or 22 by the third contact plugs CP2.

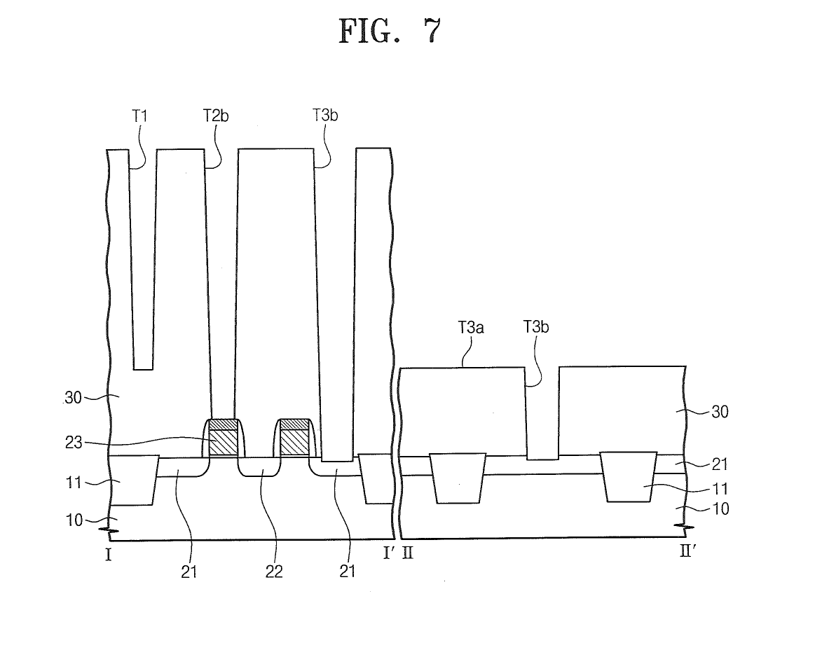

FIGS. 7 through 10 are sectional views taken along lines I-I′ and II-II′ of FIG. 1 to illustrate a method of fabricating a semiconductor device according to example embodiments of the inventive concept.

Referring to FIGS. 1 and 7, the device isolation layer 11 may be formed on the semiconductor substrate 10 to define the active regions ACT. The device isolation layer 11 may be formed by forming a trench in the semiconductor substrate 10 and filling the trench with an insulating material. The device isolation layer 11 may include at least one of oxide, nitride, or oxynitride.

A gate insulating layer and a gate conductive layer may be sequentially deposited on the semiconductor substrate 10 with the active regions ACT and be patterned to form the gate electrodes 23. Here, the gate electrodes 23 may extend parallel to the first direction D1 and cross the active regions ACT. The gate electrodes 23 may be formed of a doped polysilicon layer or a conductive layer, whose work-function is higher than that of doped polysilicon. For example, the conductive layer of the gate electrodes 23 may be at least one of a metal layer (e.g., of tungsten or molybdenum), a conductive metal nitride layer (e.g., of titanium nitride, tantalum nitride, tungsten nitride, and titanium aluminum), or a metal silicide layer (e.g., of tungsten silicide). The gate insulating layer may include oxide, nitride, oxynitride, and/or a high-k material including insulating metal oxide (e.g., hafnium oxide and aluminum oxide).

Further, the source and drain impurity regions 21 and 22 may be formed by injecting impurities into the active regions ACT at both sides of each of the gate electrodes 23.

Thereafter, the first interlayered insulating layer 30 may be formed on the semiconductor substrate 10 to cover the gate electrodes 23. The first interlayered insulating layer 30 may be formed of, for example, high-density plasma (HDP) oxide, tetraethylorthosilicate (TEOS), plasma enhanced tetraethylorthosilicate (PE-TEOS), O₃-tetra ethyl ortho silicate (O3-TEOS), Undoped Silicate Glass (USG), phosphosilicate glass (PSG), borosilicate glass (BSG), borophosphosilicate glass (BPSG), fluoride silicate glass (FSG), spin on glass (SOG), tonen silazene (TOSZ), or any combination thereof. In certain embodiments, the first interlayered insulating layer 30 may include at least one of silicon nitride, silicon oxynitride, or low-k materials.

Referring to FIG. 7, the first interlayered insulating layer 30 may be patterned to form the first trench T1, the second trench T2a and T2b, and the third trench T3a and T3b. The patterning of the first interlayered insulating layer 30 may include forming an etching mask pattern (not shown) on the first interlayered insulating layer 30 and anisotropically etching the first interlayered insulating layer 30 using the etching mask pattern as an etch mask.

As a result of the anisotropic etching process, each of the first, second, and third trenches T1, T2a, T2b, T3a, and T3b may have a decreasing width from the top to the bottom or have a downward taper shape. Further, as a result of a micro loading effect in the anisotropic etching process to the first interlayered insulating layer 30, an etching depth of the first interlayered insulating layer 30 may be changed depending on a top width of an opening in the etching mask pattern. For example, the etching depth of the first interlayered insulating layer 30 may be changed depending on the top widths of the first, second, and third trenches T1, T2a, T2b, T3a, and T3b.

In detail, when viewed in plan view, the first trench T1 may be overlapped with the device isolation layer 11 and extend along the first direction D1 with a uniform top width of W1. As a result of the anisotropic etching process, the first trench T1 may be formed to have a slanted sidewall, and thus, in certain embodiments, a bottom width of the first trench T1 may be smaller than about ½ of the top width W1. In addition, as a result of the micro loading effect in the anisotropic etching process, the bottom surface of the first trench T1 may be spaced apart from the top surface of the semiconductor substrate 10. Alternatively, as shown in FIG. 6, the first trench T1 may be formed to have the bottom surface exposing the top surface of the device isolation layer 11.

When viewed in plan view, the second trench may be overlapped with the gate electrode 23 and extend along the first direction D1. The second trench may include the first portions T2a and the second portion T2b between the first portions T2a. The first portions T2a may have a substantially uniform top width (e.g., the first top width W1), and the second portion T2b may have the second top width W2 larger than the first top width W1. In example embodiments, the first top width W1 of the second trench may be substantially equal to the top width W1 of the first trench T1, and the second top width W2 of the second trench may be larger than the top width W1 of the first trench T1.

Since the first portions T2a and the second portion T2b of the second trench have different top widths W1 and W2 from each other, there may be a difference in the micro loading effect between the first portions T2a and the second portion T2b, when the anisotropic etching process for forming the second trench is performed. For example, the etching depth may be smaller in the first portions T2a of the second trench than in the second portion T2b of the second trench. Accordingly, the bottom surface of the first portions T2a of the second trench may be spaced apart from the top surface of the semiconductor substrate 10, and the second portion T2b of the second trench may be formed to expose the top surface of the gate electrode 23.

When viewed in plan view, the third trench may extend along the first direction D1 and be overlapped with a portion of the source or drain impurity region 21 or 22. Similar to the second trench, the third trench may include the first portions T3a having substantially a uniform top width (e.g., the first top width W1) and the second portion T3b disposed between the first portions T3a to have the third top width W3 larger than the first top width W1.

Since the first and second portions T3a and T3b of the third trench have different top widths W1 and W3, the etching depth of the third trench may be larger in the second portion T3b than in the first portions T3a. According to example embodiments of the inventive concept, the bottom surface of the first portions T3a of the third trench may be spaced apart from the top surface of the semiconductor substrate 10, and the second portion T3b of the third trench may expose a portion of the source or drain impurity region 21 or 22.

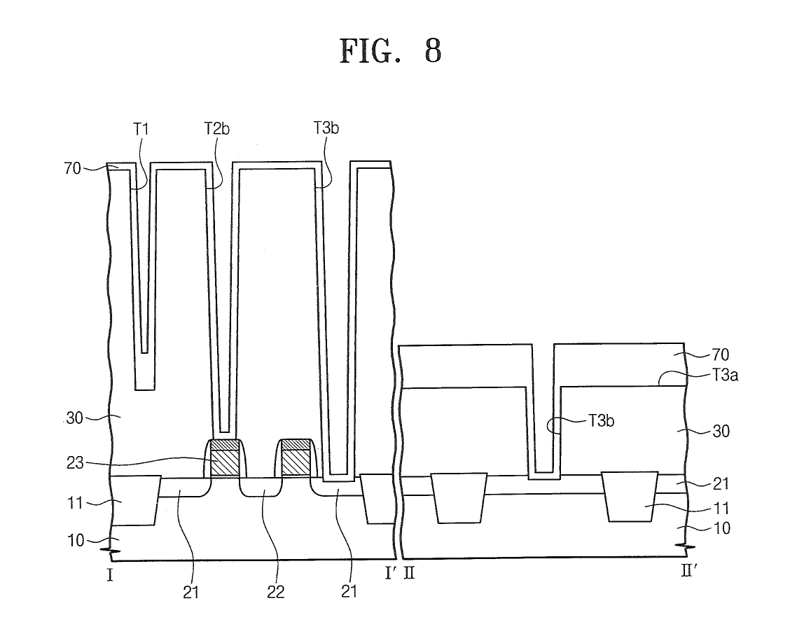

Referring to FIG. 8, a spacer layer 70 may be formed on the first interlayered insulating layer 30 with the first, second, and third trenches. The spacer layer 70 may be formed of an insulating material and have a thickness smaller than about ½ of the top width W1 of the first trench T1. For example, the spacer layer 70 may be formed of silicon oxide, silicon nitride, silicon oxynitride, or low-k materials. The spacer layer 70 may be deposited by deposition techniques (e.g., a chemical vapor deposition (CVD) technique or an atomic layer deposition (ALD) technique) capable of exhibiting a high step coverage property.

In detail, the spacer layer 70 may be uniformly deposited on the sidewalls of the first to third trenches T1, T2a, T2b, T3a, and T3b. In the case where the first trench T1 and the first portions T2a and T3a of the second and third trenches are formed to have bottom widths smaller than half the top widths W1 thereof, the spacer layer 70 may be thickly deposited on the bottom surfaces of the first trench T1 and the first portions T2a and T3a of the second and third trenches. Further, the thickness of the spacer layer 70 on the bottom surfaces of the second portions T2b and T3b of the second and third trenches may be substantially equal to that of the spacer layer 70 on the sidewalls of the first to third trenches.

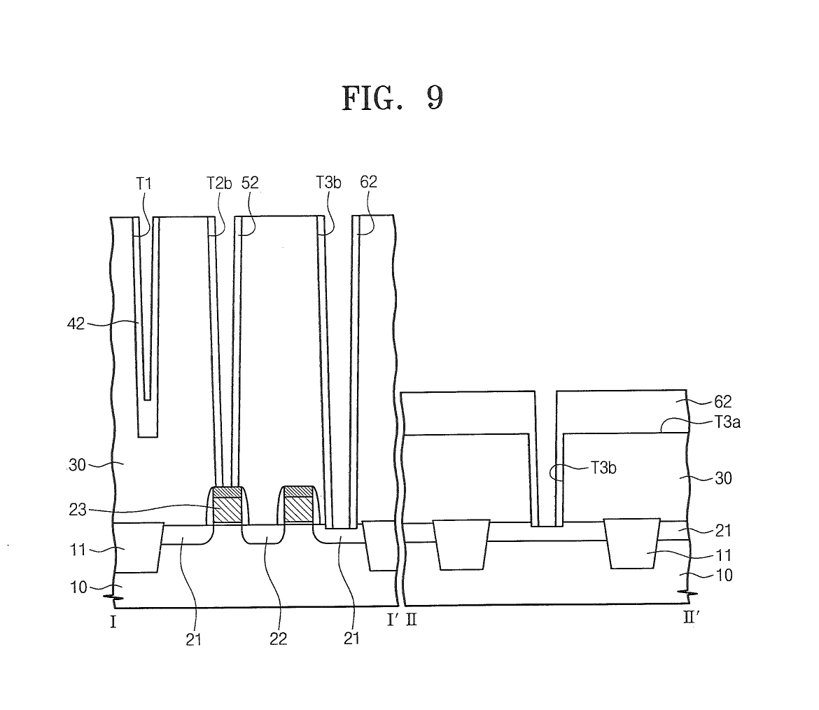

Referring to FIG. 9, the spacer layer 70 may be anisotropically etched (e.g., using an etch-back process) to form the first insulating spacer 42 in the first trench T1, the second insulating spacer 52 in the second trench, and the third insulating spacer 62 in the third trench.

In example embodiments, the etch-back process of the spacer layer 70 may be performed to expose the semiconductor substrate 10 on the second portions T2b and T3b of the second and third trenches. Further, the etch-back process of the spacer layer 70 may be performed to expose the top surface of the first interlayered insulating layer 30. Here, the spacer layer 70 may have a reduced thickness on the bottom surface of the first trench T1, but a portion of the spacer layer 70 may remain on the bottom surface of the first trench T1. Similarly, a portion of the spacer layer 70 may remain on the bottom surfaces of the first portions of the second and third trenches.

In other words, the first insulating spacer 42 may cover the side and bottom surfaces of the first trench T1 and be thicker on the bottom surface of the first trench T1 than on the side surface of the first trench T1. The second insulating spacer 52 may cover the side surfaces of the first and second portions T2a and T2b of the second trench and the bottom surface of the first portions T2a of the second trench, and it may expose locally the top surface of the gate electrode 23 through the second portion T2b. The second insulating spacer 52 may be thicker on the bottom surfaces of the first portions T2a than on the side surfaces of the first and second portions T2a and T2b of the second trench. The third insulating spacer 62 may cover the side surfaces of the first and second portions T2a and T2b and the bottom surfaces of the first portions T2a, and it may expose locally the top surface of the source or drain impurity region 21 or 22 through the second portion T2b. The third insulating spacer 62 may be thicker on the bottom surfaces of the first portions T3a than on the side surfaces of the first and second portions T3a and T3b of the third trench.

In other example embodiments, as shown in FIG. 4, the anisotropic etching process of the spacer layer 70 may be performed to expose partially upper sidewalls of the first to third trenches T1, T2a, T2b, T3a, and T3b.

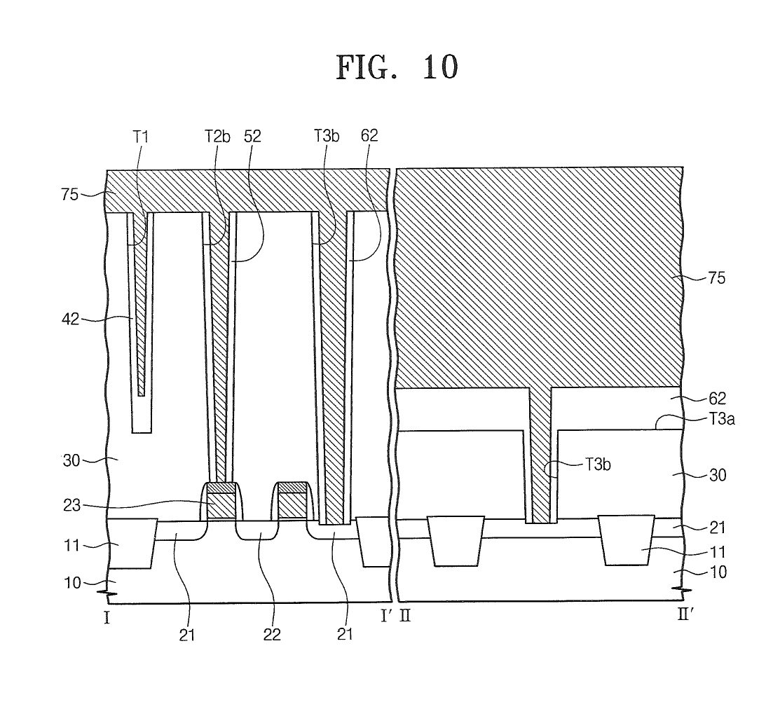

Referring to FIG. 10, a conductive layer 75 may be formed to fill the first to third trenches T1, T2a, T2b, T3a, and T3b with the first to third insulating spacers 42, 52, and 62.

The conductive layer 75 may be formed of at least one metallic material (e.g., tungsten), and in this case, the formation of the conductive layer 75 may include sequentially forming a barrier metal layer (e.g., of metal nitride) and a metal layer (e.g., of tungsten). The conductive layer 75 may be formed using deposition techniques (e.g., CVD or ALD).

After the deposition of the conductive layer 75, a planarization process may be performed to the conductive layer 75 to expose the top surface of the first interlayered insulating layer 30. As a result, the first to third interconnection structures 40, 50, and 60 may be formed, as shown in FIG. 2. In detail, the first wiring portion 44 may be formed in the first trench T1, the second wiring portion 54 may be formed in the first portions T2a of the second trench and the second contact portion 56 may be formed in the second portion T2b of the second trench. Further, the third wiring portion 64 may be formed in the first portions T3a of the third trench and the third contact portion 66 may be formed in the second portion T3b of the third trench.

Thereafter, the second interlayered insulating layer 80 may be formed on the first interlayered insulating layer 30. The first to third contact plugs CP1, CP2, and CP3 may be formed in the second interlayered insulating layer 80, and the upper interconnection lines ICL may be formed on the second interlayered insulating layer 80 to extend along the second direction D2.

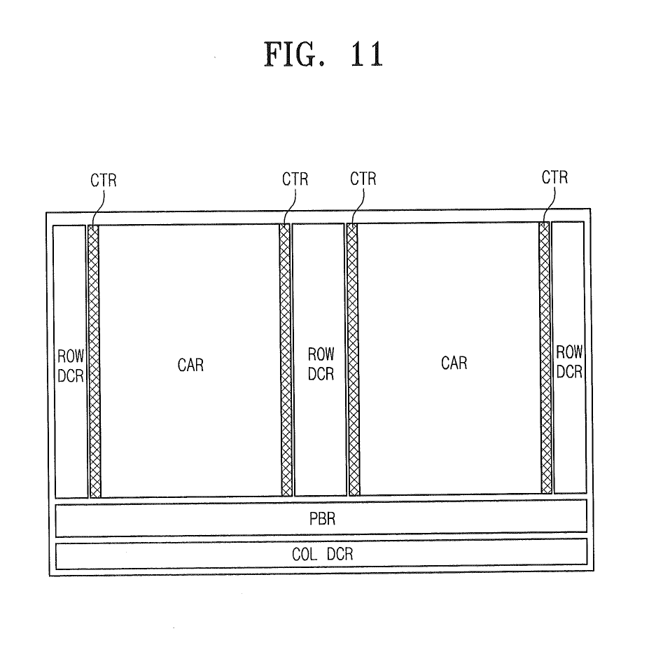

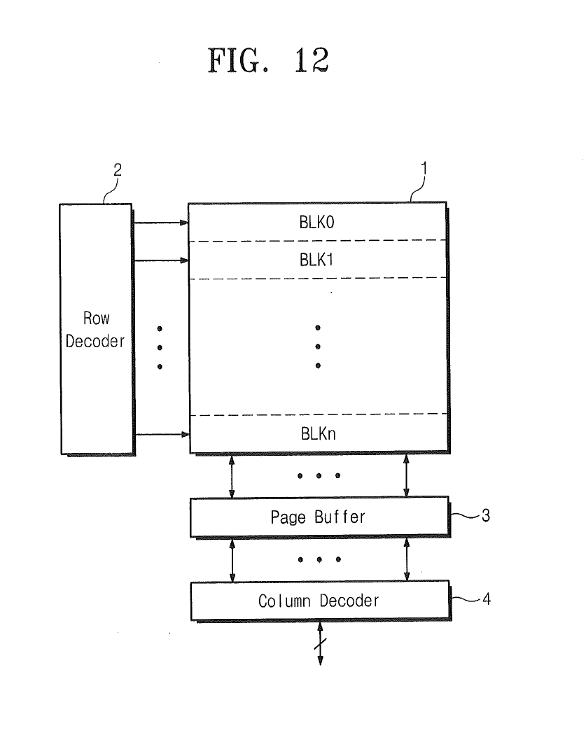

FIG. 11 is a plan view schematically illustrating a structure of a semiconductor memory device according to example embodiments of the inventive concept. FIG. 12 is a block diagram illustrating a semiconductor memory device according to example embodiments of the inventive concept.

Referring to FIG. 11, a semiconductor memory device may include a cell array region CAR and a peripheral circuit region PERI. The peripheral circuit region PERI may include row decoder regions ROW DCR, a page buffer region PBR, and a column decoder region COL DCR. Furthermore, a contact region may be disposed between the cell array region CAR and the row decoder regions ROW DCR.

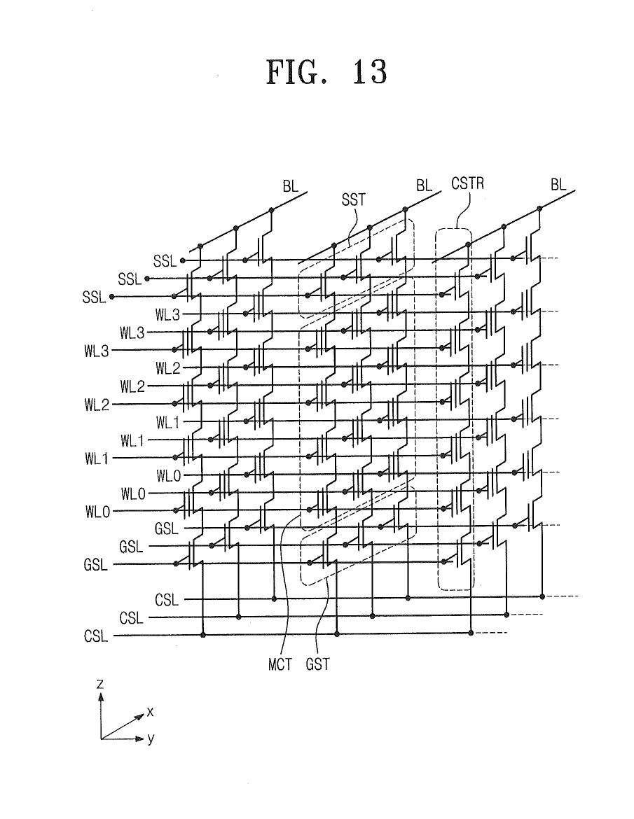

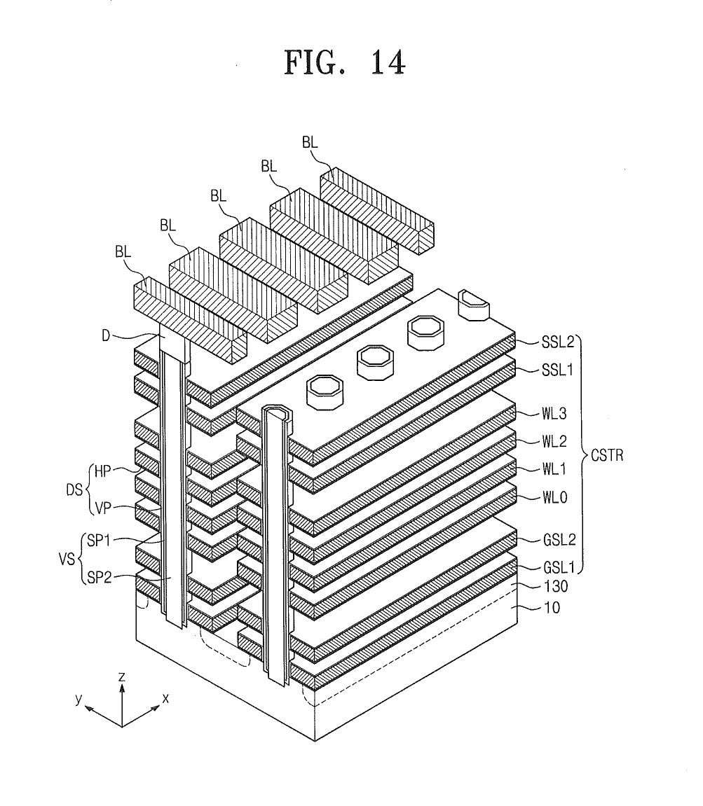

Referring to FIGS. 11 and 12, a memory cell array 1 may be provided on the cell array region CAR. The memory cell array 1 may include a plurality of memory cells and a plurality of word lines and a plurality of bit lines electrically connected to the memory cells. In example embodiments, the memory cell array 1 may include a plurality of memory blocks BLK0-BLKn, where each memory block is a unit data size of a data erase operation. The memory cell array 1 will be described in more detail with reference to FIGS. 13 and 14.

A row decoder 2 may be provided in the row decoder region ROW DCR to select word lines in the memory cell array 1. A interconnection structure may be provided in the contact region to connect the memory cell array 1 electrically to the row decoder 2. The row decoder 2 may select one of the memory blocks BLK0-BLKn of the memory cell array 1 and one of word lines in the selected memory block, based on address information. The row decoder 2 may be configured to provide word line voltages, which may be generated by a voltage generating circuit (not shown), to the selected and non-selected word lines, in response to control signals from a control circuit (not shown).

A page buffer 3 may be provided in the page buffer region PBR to read out data stored in the memory cells. Depending on an operation mode, the page buffer 3 may be configured to store temporarily data to be stored in the memory cells or read out or sense data stored in the memory cells. For example, the page buffer 3 may serve as a write driver circuit in the programming operation mode and serve as a sense amplifier circuit in the reading operation mode.

A column decoder 4 may be provided in the column decoder region COL DCR and be connected to the bit lines in the memory cell array 1. The column decoder 4 may provide paths for transmitting data between the page buffer 3 and an external device (e.g., a memory controller).

FIG. 13 is a circuit diagram schematically illustrating a cell array region of a semiconductor memory device, according to example embodiments of the inventive concept.

Referring to FIG. 13, in example embodiments of the inventive concept, the cell array of the three-dimensional semiconductor memory device may include at least one common source line CSL, a plurality of bit lines BL, and a plurality of cell strings CSTR interposed between the common source line CSL and the bit lines BL.

The bit lines BL may be two-dimensionally arranged and a plurality of the cell strings CSTR may be connected in parallel to each of the bit lines BL. The cell strings CSTR may be connected in common to the common source line CSL. In other words, the plurality of the cell strings CSTR may be disposed between each of the bit lines BL and the common source line CSL. In example embodiments, the cell array region CAR may include a plurality of common source lines CSL two-dimensionally arranged. Here, the common source lines CSL may be connected to each other to be in an equipotential state. In other example embodiments, the common source lines CSL may be electrically separated from each other, and thus, they can be independently controlled.

Each of the cell strings CSTR may include a ground selection transistor GST coupled to the common source line CSL, a string selection transistor SST coupled to the bit line BL, and a plurality of memory cell transistors MCT disposed between the ground and string selection transistors GST and SST. Here, the ground selection transistor GST, the memory cell transistors MCT, and the string selection transistor SST may be connected in series.

The common source line CSL may be connected in common to sources regions of the ground selection transistors GST. In addition, the ground selection line GSL, the word lines WL0-WL3, and the string selection lines SSL disposed between the common source line CSL and the bit lines BL may serve as gate electrodes of the ground selection transistor GST, the memory cell transistors MCT, and the string selection transistors SST, respectively. Moreover, each of the memory cell transistors MCT may include a data storage element.

FIG. 14 is a perspective view illustrating a cell array region of a semiconductor memory device according to example embodiments of the inventive concept.

Referring to the example of FIG. 14, the common source line CSL may be provided as a conductive layer on the substrate 10 or provided as an impurity region in the substrate 10. The bit lines BL may be conductive patterns (e.g., metal lines) disposed over the substrate 10. The bit lines BL may be two-dimensionally arranged over the substrate 10 and the plurality of the cell strings CSTR may be connected in parallel to each of the bit lines BL. Accordingly, the cell strings CSTR may be two-dimensionally disposed on the common source line CSL or the substrate 10.

Each of the cell strings CSTR may include a plurality of ground selection lines GSL1 and GSL2, a plurality of word lines WL0 to WL3, and a plurality of string selection lines SSL and SSL2, which are interposed between the common source line CSL and the bit lines BL. In example embodiments, the string selection lines SSL1 and SSL2 may be used as the string selection line SSL of FIG. 13, and the ground selection lines GSL1 and GSL2 may be used as the ground selection line GSL of FIG. 13. Further, the ground selection lines GSL1 and GSL2, the word lines WL0 to WL3, and the string selection lines SSL1 and SSL2 may be conductive patterns (or gate patterns) stacked on the substrate 10.

Each of the cell strings CSTR may include a vertical structure VS vertically extending from the common source line CSL and being connected to the bit line BL. The vertical structure VS may be formed to penetrate the ground selection lines GSL1 and GSL2, the word lines WL0-WL3, and the string selection lines SSL1 and SSL2. In other words, the vertical structures VS may penetrate a plurality of conductive patterns stacked on the substrate 10.

The vertical structures VS may include a semiconductor material or a conductive material. In example embodiments, the vertical structure VS may be formed of a semiconductor material and may include a semiconductor body portion SP2 connected to the semiconductor substrate 10 and a semiconductor spacer SP1 interposed between the semiconductor body portion SP2 and a data storing layer DS, as shown in FIG. 12A. Furthermore, the vertical structures VS may include impurity regions D provided in upper portions thereof.

The data storing layer DS may be disposed between the word lines WL0-WL3 and the vertical structures VS. In example embodiments, the data storing layer DS may be a charge storing layer. For example, the data storing layer DS may be one of a trap insulating layer, a floating gate electrode, or an insulating layer with conductive nanodots. Data stored in the data storing layer DS may be changed using a Fowler-Nordheim FN tunneling effect, which may be caused by a voltage difference between the vertical structure VS and the word lines WL0-WL3. Alternatively, the data storing layer DS may be configured in such a way that data therein can be changed by other operational principle. For example, the data storing layer DS may include a phase changeable layer or a variable resistance layer.

In example embodiments, the data storing layer DS may include a vertical pattern VP penetrating the word lines WL0-WL3 and a horizontal pattern HP disposed between the word lines WL0-WL3 and the vertical pattern VP to cover top and bottom surfaces of the word lines WL0-WL3.

A dielectric layer serving as a gate insulating layer of a transistor may be provided between the ground selection lines GSL1 and GSL2 and the vertical structures VS or between the string selection lines SSL1 and SSL2 and the vertical structure VS. Here, the dielectric layer may be formed of the same material as the data storing layer DS and, in certain embodiments, it may be a gate insulating layer (for example, a silicon oxide layer) of a conventional MOSFET.

In this structure, the vertical structures VS may constitute a metal-oxide-semiconductor field effect transistor (MOSFET) using the vertical structure VS as a channel region, in conjunction with the ground selection lines GSL1 and GSL2, the word lines WL0-WL3, and the string selection lines SSL1 and SSL2. Alternatively, the vertical structures VS may constitute a MOS capacitor, in conjunction with the ground selection lines GSL1 and GSL2, the word lines WL0-WL3, and the string selection lines SSL1 and SSL2.

In this case, the ground selection lines GSL1 and GSL2, the word lines WL0-WL3, and the string selection lines SSL1 and SSL2 may serve as gate electrodes of the selection transistors and the cell transistors. Further, due to the presence of fringe field from the ground selection lines GSL1 and GSL2, the word lines WL0-WL3, and the string selection lines SSL1 and SSL2, inversion regions may be formed in the vertical structures VS. Here, the inversion region may be formed to have a width greater than a thickness of each of the word or selection lines. For example, the inversion regions may be vertically overlapped with each other in the vertical structures VS, thereby serving as a current path connecting a common source region 130 electrically to a selected bit line.

In other words, the ground and string transistors controlled by the lower and upper selection lines GSL1, GSL2, SSL1, and SSL2 and the cell transistors MCT controlled by the word lines WL0-WL3 may be connected in series, in the cell string CSTR.

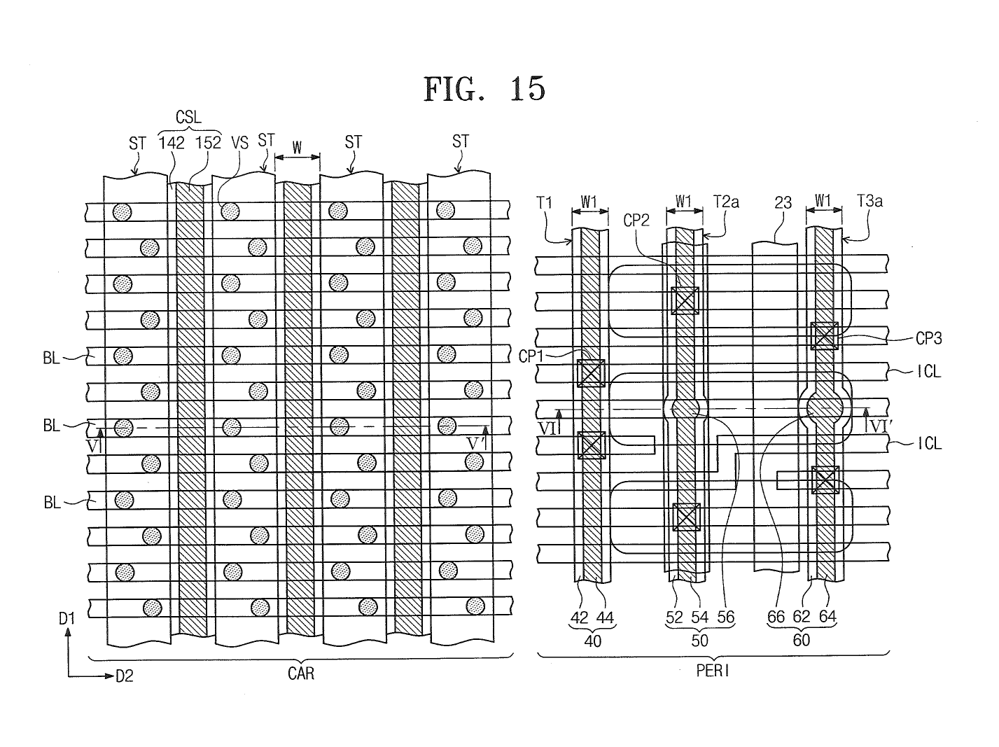

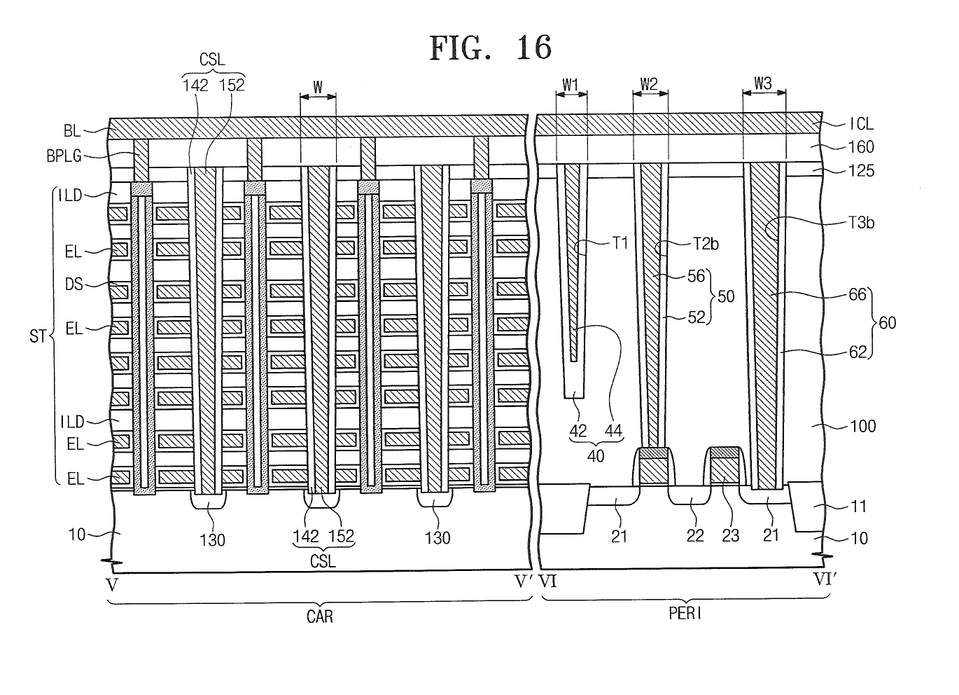

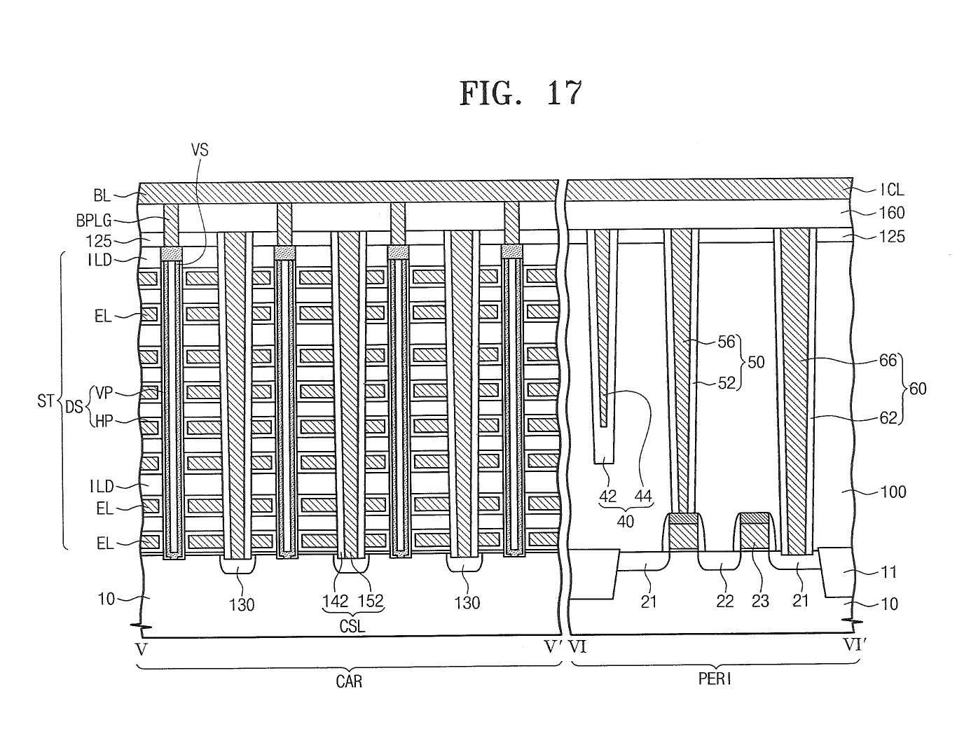

FIG. 15 is a plan view illustrating a semiconductor memory device according to example embodiments of the inventive concept. FIG. 16 is a sectional view taken along lines V-V′ and VI-VI′ of FIG. 15 to illustrate a semiconductor memory device according to example embodiments of the inventive concept. FIG. 17 is a sectional view taken along lines V-V′ and VI-VI′ of FIG. 15 to illustrate a semiconductor memory device according to other example embodiments of the inventive concept.

Referring to FIGS. 15 and 16, a substrate 10 may include the cell array region CAR and the peripheral circuit region PERI.

The substrate 10 may be a substrate having a semiconductor property (e.g., a silicon wafer), an insulating substrate (e.g., a glass substrate), or a semiconductor or conductor covered with an insulating material. For example, the substrate 10 may be a silicon wafer having a first conductivity type.

In example embodiments, a cell array structure may be provided on the cell array region CAR of the substrate 10, and a peripheral logic structure may be provided on the peripheral circuit region PERI of the substrate 10. When measured from the top surface of the substrate 10, the cell array structure may have a first height and the peripheral logic structure may have a second height smaller than the first height.

For example, the cell array structure may include a plurality of stacks ST, each of which includes electrodes EL and insulating layers ILD alternatingly stacked on the substrate 10, and the vertical structures VS penetrating the stack ST. As shown, the stacks ST may extend along the first direction D1 and be spaced apart from each other in the second direction D2. Further, the stacks ST may have slanted sidewalls.

The insulating layers ILD constituting the stacks ST may have at least two different thicknesses. For example, the lowermost one of the insulating layers ILD may have a thickness smaller than that of the others. Alternatively, some of the insulating layers ILD may be formed to have a larger thickness than the remaining ones of the insulating layers ILD. In certain embodiments, the insulating layers ILD may include silicon oxide.

The electrodes EL of the stacks ST may include a conductive material. For example, the electrodes EL may include at least one of doped semiconductor (e.g., doped silicon), metal (e.g., tungsten, copper, aluminum, and so forth), conductive metal nitride (e.g., titanium nitride, tantalum nitride, and so forth), or transition metal (e.g., titanium, tantalum, and so forth).

In example embodiments, the vertical structures VS may be connected to the substrate 10 through the stack ST. The vertical structures VS may include a semiconductor material or a conductive material. In example embodiments, the vertical structure VS may include a semiconductor body portion SP1 connected to the substrate 10 and a semiconductor spacer SP2 interposed between the semiconductor body portion SP and the data storing layer DS, as described with reference to FIG. 14. In example embodiments, when viewed in plan view, the vertical structures VS may be arranged in a zigzag manner along a specific direction. Alternatively, when viewed in plan view, the vertical structure VS may be linearly arranged along a specific direction.

According to the embodiment shown in FIG. 16, the data storing layer DS may be provided between the electrodes EL and the vertical structure VS to cover the top and bottom surfaces of the electrodes EL. By contrast, according to the embodiment shown in FIG. 17, the data storing layer DS may include a vertical insulating pattern VP vertically extending between the electrodes EL and the stack ST and a horizontal insulating pattern HP disposed between the vertical insulating pattern VP and the electrodes EL to cover the top and bottom surfaces of the electrodes EL.

In addition, the common source regions 130 may be formed in the substrate 10 between the stacks ST. The common source regions 130 may extend parallel to the first direction D1 and be spaced apart from the second direction. The common source regions 130 may be formed by doping portions of the substrate 10 with impurities, whose conductivity type is different from that of the substrate 10.

In example embodiments, a common source structure CSL may be provided between an adjacent pair of the stacks ST. The common source structure CSL may include an insulating sidewall spacer 142, which may be formed to cover sidewalls of the stacks ST, and the common source line 152, which may be formed through the insulating sidewall spacer 142 and be connected to the common source region 130. The common source structure CSL may have a substantially uniform top width and extend parallel to the first direction D1. The insulating sidewall spacer 142 may be provided between an adjacent pair of the stacks ST to face each other.

The insulating sidewall spacer 142 may be formed of silicon oxide, silicon nitride, silicon oxynitride, or low-k materials. The common source line 152 may include at least one of metals (e.g., tungsten, copper or aluminum), conductive metal nitrides (e.g., titanium nitride, or tantalum nitride), and transition metals (e.g., titanium or tantalum).

An interlayered insulating layer 160 may be provided on the stacks ST and the common source structure CSL, and the bit lines BL may be provided on the interlayered insulating layer 160 to cross the stacks ST and extend parallel to the second direction D2. The bit lines BL may be electrically connected to the vertical structure VS through bit line contact plugs BPLG, which are formed to penetrate the interlayered insulating layer 160.

In example embodiments, as described with reference to FIGS. 11 and 12, the peripheral logic structure of the peripheral circuit region PERI may include the row and column decoders (e.g., 2 and 4 of FIG. 12), the page buffer (e.g., 3 of FIG. 12), and the control circuits. The peripheral logic structure may include NMOS and PMOS transistors, resistors, and capacitors, which may be electrically connected to the cell array structure.

In detail, the device isolation layer 11 may be formed on the peripheral circuit region PERI of the substrate 10 to define the active region ACT. The peripheral logic structure of the peripheral circuit region PERI may include the peripheral word line 23, which may extend across the active region ACT and parallel to the first direction D1, and the source and drain impurity regions 21 and 22, which may be formed in portions of the active region ACT at both sides of the peripheral word line 23.

An insulating gap-fill layer 100 may be provided on the peripheral logic structure, and the insulating gap-fill layer 100 may have a top surface that is coplanar with those of the stacks ST or the vertical structures VS. Further, a capping insulating pattern 125 coplanar with the top surfaces of the common source structures CSL of the cell array region CAR may be provided on the insulating gap-fill layer 100.

The insulating gap-fill layer 100 and the capping insulating pattern 125 provided on the peripheral circuit region PERI may have the first, second, and third trenches, in which the first, second, and third interconnection structures 40, 50, and 60, respectively, are provided.

According to the present embodiment, the first to third interconnection structures 40, 50, and 60 of the peripheral circuit region PERI may have top surfaces that are substantially coplanar with those of the common source structures CSL of the cell array region CAR.

In detail, the first trench T1 may extend parallel to the first direction D1 with a uniform top width W1. In example embodiments, the top width W1 of the first trench T1 may be smaller than a top width W of the common source structure CSL. The first trench T1 may have a bottom surface spaced apart from the top surface of the substrate 10 and a sidewall at an angle to the top surface of the substrate 10. In example embodiments, the bottom width of the first trench T1 may be smaller than or equivalent to about ½ of the top width W1, and the vertical length of the first trench T1 may be changed depending on the top width W1 of the first trench T1.

The first interconnection structure 40 may include the first insulating spacer 42 and the first wiring portion 44, as described with reference to FIGS. 1 through 6. The first insulating spacer 42 may cover an inner wall of the first trench T1, conformally. Alternatively, in the case where the first trench T1 has a tapered shape, a thickness of the first insulating spacer 42 may be larger on the bottom surface of the first trench T1 than on the sidewall of the first trench T1. For example, the thickness of the first insulating spacer 42 on the sidewall of the first trench T1 may be smaller than about ½ of the top width W1 of the first trench T1, and the thickness of the first insulating spacer 42 on the bottom surface of the first trench T1 may be larger than about 2 times the top width W1 of the first trench T1. The first wiring portion 44 may be formed of the same conductive material as that for the common source line CSL. Further, the first wiring portion 44 may extend parallel to the first direction D1 and be spaced apart from the top surface of the substrate 10.

When viewed in plan view, the second trench may be overlapped with the peripheral word line 23 and extend along the first direction D1. The second trench may include the first portions T2a and the second portion T2b between the first portions T2a. The first portions T2a may have a substantially uniform top width (e.g., the first top width W1), and the second portion T2b may have the second top width W2 larger than the first top width W1. In example embodiments, the first and second top widths W1 and W2 of the second trench may be smaller than the top width W of the common source structure CSL. Further, each of the first portions T2a of the second trench may have a bottom surface spaced apart from the top surface of the substrate 10 and a side surface at an angle to the top surface of the substrate 10. The second portion T2b of the second trench may be formed to expose a top surface of the peripheral word line 23 and have a round side surface in a plan view.

The second interconnection structure in the second trench may include the second insulating spacer 52, the second wiring portion 54, and the second contact portion 56, as described with reference to FIGS. 1 through 6.

In example embodiments, the second insulating spacer 52 may cover the side and bottom surfaces of the first portions T2a of the second trench and cover the side surface of the second portion T2b of the second trench. In other words, the second insulating spacer 52 may expose locally the gate electrode through the second portion T2b of the second trench. Further, the second insulating spacer 52 may be formed to be thicker on the bottom surface of the first portions T2a than on the side surface of the first portions T2a.

The second wiring portion 54 and the second contact portion 56 may be provided in the second trench provided with the second insulating spacer 52. For example, the second wiring portion 54 may be provided in the first portions T2a of the second trench and extend parallel to the first direction D1. The second contact portion 56 may be provided in the second portion T2b of the second trench. In certain embodiments, a vertical length of the second contact portion 56 may be larger than that of the second wiring portion 54. The second wiring portion 54 and the first wiring portion 44 may have substantially the same top width, and the second contact portion 56 may have a top width larger than that of the second wiring portion 54. The second wiring portion 54 and the second contact portion 56 may be formed of the same conductive material as that for the common source line CSL.

When viewed in plan view, the third trench may extend parallel to the first direction D1 and be partially overlapped with the source or drain impurity region 21 or 22. Similar to the second trench, the third trench may include the first portions T3a having substantially a uniform top width (e.g., the first top width W1) and the second portion T3b disposed between the first portions T3a to have the third top width W3 larger than the first top width W1. In example embodiments, the first top width W1 of the third trench may be smaller than the top width W of the common source structure CSL, and the third top width W3 of the third trench may be greater than the top width W of the common source structure CSL. Further, in the third trench, the first portions T3a may have the bottom surfaces spaced apart from the top surface of the substrate 10 and have the side surface at an angle to the top surface of the substrate 10. In addition, the second portion T3b of the third trench may be formed to expose a portion of the source or drain impurity region 21 or 22.

The third interconnection structure 60 in the third trench may include the third insulating spacer 62, the third wiring portion 64, and the third contact portion 66, as described with reference to FIGS. 1 through 6.

In example embodiments, the third insulating spacer 62 may cover side and bottom surfaces of the first portions T3a of the third trench and cover the side surface of the second portion T3b of the third trench. In other words, the third insulating spacer 62 may expose locally the source or drain impurity region 21 or 22 below the second portion T3b of the third trench. Further, the third insulating spacer 62 may be formed to be thicker on the bottom surface of the first portions T3a of the third trench than on the side surface of the third trench.

The third wiring portion 64 and the third contact portion 66 may be provided in the third trench provided with the third insulating spacer 62. For example, the third wiring portion 64 may be provided in the first portions T3a of the third trench to extend parallel to the first direction D1. The third contact portion 66 may be provided in the second portion T3b of the third trench. In certain embodiments, a vertical length of the third contact portion 66 may be larger than that of the second contact portion 56. A top width of the third wiring portion 64 may be substantially the same as that of the second wiring portion 54, and a top width of the third contact portion 66 may be larger than that of the second contact portion 56. The third wiring portion 64 and the third contact portion 66 may be formed of the same conductive material as that for the common source line CSL.

In example embodiments, the interlayered insulating layer 160 may be formed to cover the top surfaces of the common source structure CSL and the first to third interconnection structures 40, 50, and 60.

The bit lines BL may be provided on the interlayered insulating layer 160 of the cell array region CAR to cross the stack ST and extend parallel to the second direction D2. The bit lines BL may be electrically connected to the vertical structure VS through the bit line contact plugs BPLG.

The upper interconnection lines ICL may be provided on the interlayered insulating layer 160 of the peripheral circuit region PERI. The upper interconnection lines ICL may extend from the peripheral circuit region PERI to the cell array region CAR. In certain embodiments, the upper interconnection lines ICL may be formed of the same conductive material as that for the bit lines BL of the cell array region CAR.

The upper interconnection lines ICL may extend parallel to the second direction D2 or perpendicular to the first direction D1, and the upper interconnection lines ICL may be partially overlapped with the active region ACT, when viewed in plan view. For example, a plurality of the upper interconnection lines ICL may be disposed over each of the active regions ACT.

As described with reference to FIGS. 1 through 6, when viewed in a vertical section, the first to third contact plugs CP1, CP2, and CP3 may be disposed between the first to third interconnection structures 40, 50, and 60 and the upper interconnection lines ICL. Further, the first to third interconnection structures 40, 50, and 60 may be electrically connected to the upper interconnection lines ICL, which may be spaced apart from each other.

In detail, the first interconnection structure 40 may be electrically connected to at least one of the upper interconnection lines ICL via the first contact plugs CP1. For example, the first interconnection structure 40 may connect the upper interconnection lines ICL, which may be spaced apart from each other, electrically to each other using the first contact plugs CP1. The first contact plugs CP1 may be connected to the first wiring portion 44 of the first interconnection structure 40, and in certain embodiments, positions of the first contact plugs CP1 may be changed to connect the upper interconnection lines ICL, which may be spaced apart from each other, electrically to each other.

The second interconnection structure 50 may be electrically connected to at least one of the upper interconnection lines ICL through the second contact plugs CP2. The second contact plugs CP2 may be connected to the second wiring portion 54 and the second contact portion 56 of the second interconnection structure 50. Since the second interconnection structure 50 is connected to the gate electrode 23, at least one interconnection line may be connected in common to the gate electrode 23 through the second interconnection structure 50.

The third interconnection structure 60 may be electrically connected to at least one of the upper interconnection lines ICL through the third contact plugs CP2. The third contact plugs CP2 may be connected to the third wiring portion 64 and the third contact portion 66 of the third interconnection structure 60. Since the third interconnection structure 60 is connected to the source or drain impurity region 21 or 22, at least one the upper interconnection lines ICL may be connected in common to the source or drain impurity region 21 or 22 through the third interconnection structure 60. Since the third interconnection structure 60 is disposed to cross the upper interconnection lines ICL, it is possible to connect easily the upper interconnection lines ICL to the source or drain impurity region 21 or 22, even in the case that, when viewed in plan view, the upper interconnection lines ICL are not overlapped with the source or drain impurity region 21 or 22.

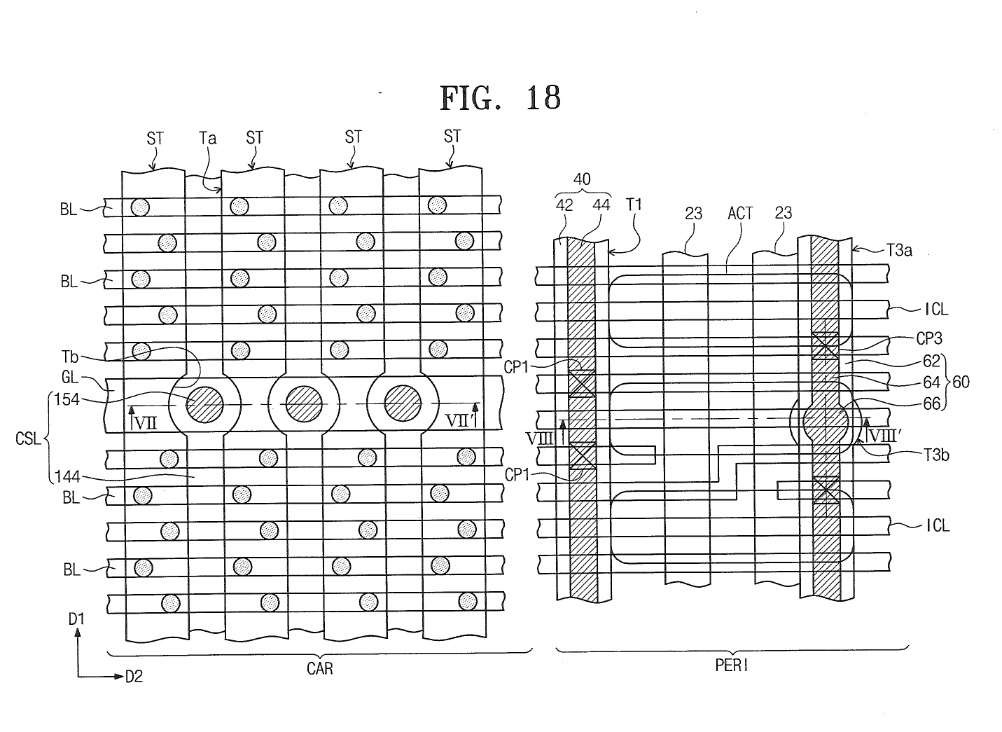

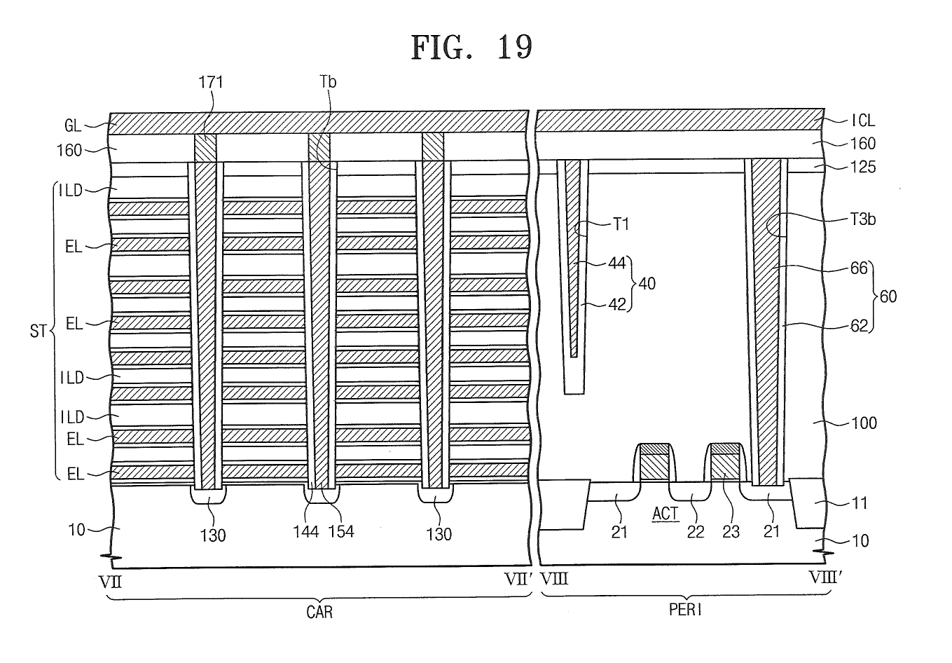

FIG. 18 is a plan view of a semiconductor memory device according to still other example embodiments of the inventive concept. FIG. 19 is a sectional view taken along lines VII-VII′ and VIII-VIII′ of FIG. 18 to illustrate a semiconductor memory device according to still other example embodiments of the inventive concept. In the following description of FIGS. 18 and 19, a previously described element may be identified by a similar or identical reference number without repeating an overlapping description thereof, for the sake of brevity.

Referring to FIGS. 18 and 19, the stacks ST may be provided on the cell array region CAR of the substrate 10 to extend parallel to the first direction D1. Here, the stacks ST may include a line region Ta having a uniform top width and a contact region Tb having a top width larger than that of the line region Ta. The contact region Th of the stacks ST may be formed to have a round sidewall, in a plan view.

The common source structure CSL may be disposed between the stacks ST. The common source structure CSL may extend parallel to the first direction D1 and include an insulating pattern 144 covering sidewalls of the stacks ST and a common source plug 154 connected to the common source region 130 through the insulating pattern 144. Here, the insulating pattern 144 may fill completely the line regions Ta of the stacks ST, and the common source plug 154 may be provided in the contact region Tb of the stacks ST. The interlayered insulating layer 160 may be provided to cover the common source structure CSL, and a connection line GL may be provided on the interlayered insulating layer 160 and be connected to the common source structure CSL. The connection line GL may extend parallel to the bit lines BL or the second direction D2.

In example embodiments, the first interconnection structure 40 and the third interconnection structure 60 may be provided on the peripheral circuit region PERI of the substrate 10 to extend along the first direction D1. The first and third interconnection structures 40 and 60 may have top surfaces that are substantially coplanar with those of the common source structure CSL. Further, the first and third interconnection structures 40 and 60 may be formed of the same conductive material as that for the common source structure CSL. The first and third interconnection structures 40 and 60 may be configured to have substantially the same structure as those of the previous embodiments described with reference to FIGS. 1 through 6.

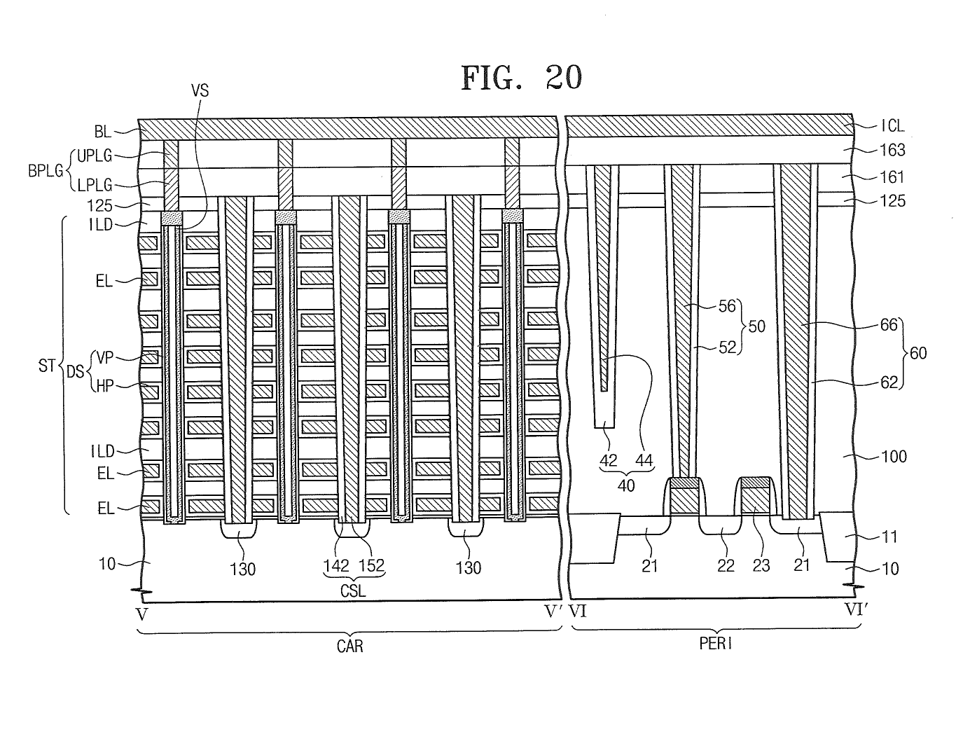

FIG. 20 is a sectional view illustrating a semiconductor memory device according to even other example embodiments of the inventive concept. In the following description of FIG. 20, a previously described element may be identified by a similar or identical reference number without repeating an overlapping description thereof, for the sake of brevity.

Referring to FIG. 20, the stacks ST may be provided on the cell array region CAR of the substrate 10 to extend parallel to the first direction D1. The common source structure CSL may be provided between an adjacent pair of the stacks ST. First and second interlayered insulating layers 161 and 163 may be sequentially stacked on the common source structure CSL to cover the peripheral circuit region PERI.

The first interconnection structure 40, the second interconnection structure 30, and the third interconnection structure 60 may be provided on the peripheral circuit region PERI of the substrate 10 to extend parallel to the first direction D1, and the upper interconnection lines ICL may be provided on the first to third interconnection structures 40, 50, and 60 to extend parallel to the second direction D2.

In example embodiments, top surfaces of the first to third interconnection structures 40, 50, and 60 may be positioned between the top surface of the common source structure CSL and the bottom surfaces of the upper interconnection lines ICL. The bit line contact plug BPLG may include a lower contact plug LPLG and an upper contact plug UPLG, and the top surfaces of the first to third interconnection structures 40, 50, and 60 may be coplanar with the top surface of the lower contact plug LPLG of the bit line contact plug BPLG.

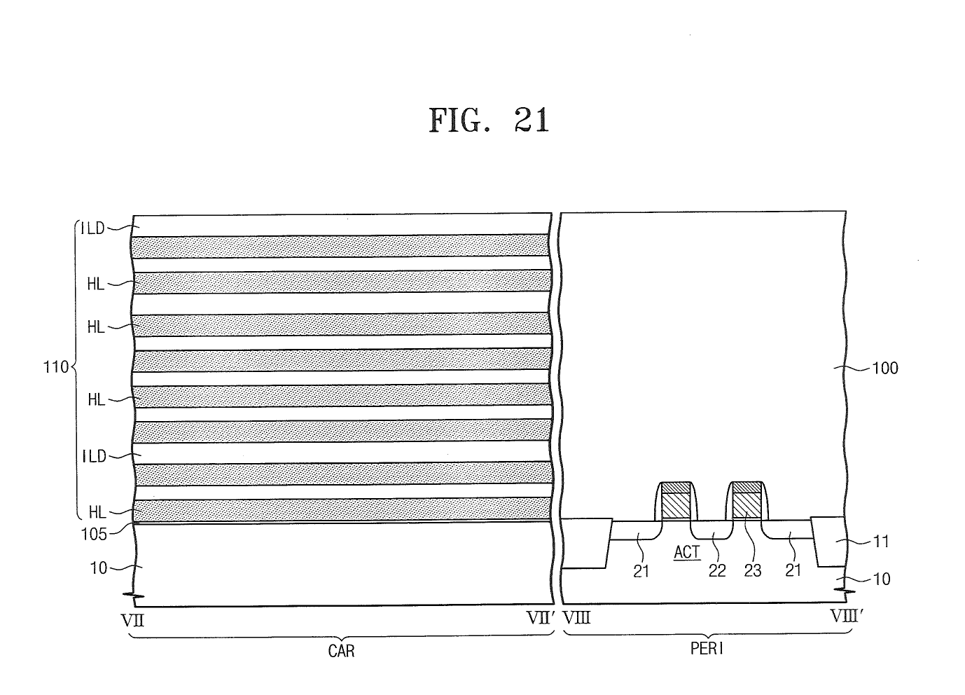

FIGS. 21 through 30 are sectional views taken along lines I-I′, II-II′, and III-III′ of FIG. 15 to illustrate a method of fabricating a semiconductor memory device according to example embodiments of the inventive concept.

Referring to FIG. 21, the substrate 10 may include the cell array region CAR and the peripheral circuit region PERI.

The substrate 10 may be a substrate having a semiconductor property (e.g., a silicon wafer), an insulating substrate (e.g., a glass substrate), or a semiconductor or conductor covered with an insulating material. For example, the substrate 10 may be a silicon wafer having a first conductivity type.

In example embodiments, the peripheral logic structure may be formed on the peripheral circuit region PERI of the substrate 10. The formation of the peripheral logic structure may include forming peripheral circuits (e.g., the row and column decoders, the page buffer, and the control circuits described with reference to FIG. 12).

In example embodiments, as shown, the formation of the peripheral logic structure may include forming peripheral transistors constituting the peripheral circuits on the peripheral circuit region PERI of the substrate 10.

For example, the formation of the peripheral transistors may include forming the device isolation layer 11 to define the active regions ACT in the peripheral circuit region PERI of the substrate 10, sequentially forming the gate insulating layer and the peripheral word line 23 on the substrate 10, and forming the source and drain impurity regions 21 and 22 in the active region ACT at both sides of the peripheral word line 23. The peripheral word line 23 may extend parallel to the first direction D1 and cross the active region ACT. The peripheral word line 23 may be used for the gate electrodes of MOS transistors constituting the peripheral circuits, and the source and drain impurity regions 21 and 22 may be used for source and drain electrodes of the MOS transistors. The peripheral word line 23 may be formed of or include a doped polysilicon layer or a metal layer, and the gate insulating layer may be or include a silicon oxide layer, which may be formed by a thermal oxidation process.

Referring to FIG. 21, sacrificial layers HL and insulating layers ILD may be alternately stacked on the cell array region CAR of the substrate 10 to form a layered structure 110. In example embodiments, the layered structure 110 may have a height that is greater than that of the peripheral logic structure. For example, the height of the layered structure 110 may be larger than twice the height of the peripheral logic structure. In other words, the top surface of the peripheral logic structure may be located below that of the layered structure 110.

In the layered structure 110, the sacrificial layers HL may be formed of a material, which can be etched with a sufficiently-high etch selectivity with respect to the insulating layers ILD. In example embodiments, the etch selectivity between the sacrificial layers HL and the insulating layers ILD may be increased in a wet etching process and decreased in a dry etching process using an etching gas.

In example embodiments, the sacrificial layers HL may have substantially the same thickness, and in other embodiments, the uppermost and lowermost layers of the sacrificial layers HL may be formed to be thicker than the others therebetween. The insulating layers ILD may have substantially the same thickness or at least one of the insulating layers ILD may have a different thickness from the others.

The sacrificial layers HL and the insulating layers ILD may be deposited using a thermal CVD process, a plasma-enhanced CVD process, a physical CVD process, or an atomic layer deposition (ALD) process.

In example embodiments, the sacrificial layers HL and the insulating layers ILD may be formed of insulating materials having an etch selectivity with respect to each other. For example, the sacrificial layers HL may be at least one of a silicon layer, a silicon oxide layer, a silicon carbide layer, a silicon oxynitride layer, or a silicon nitride layer. The insulating layers ILD may be at least one of a silicon layer, a silicon oxide layer, a silicon carbide layer, a silicon oxynitride layer, or a silicon nitride layer, but it may be formed of a material selected to be different from the sacrificial layer. For example, the sacrificial layers HL may be formed of a silicon nitride layer, while the insulating layers ILD may be formed of a silicon oxide layer. In other embodiments, the sacrificial layers HL may be formed of a conductive material, while the insulating layers ILD may be formed of an insulating material.

Furthermore, a lower insulating layer 105 may be formed between the substrate 10 and the layered structure 110. For example, the lower insulating layer 105 may be or include a silicon oxide layer, which may be formed by a thermal oxidation process. Alternatively, the lower insulating layer 105 may be or include a silicon oxide layer, which may be formed by a deposition process. The lower insulating layer 105 may be formed to be thinner than the sacrificial layers HL and the insulating layers ILD provided thereon.

After the formation of the peripheral logic structure and the layered structure 110, the insulating gap-fill layer 100 may be formed on the substrate 10 of the peripheral circuit region PERI. The insulating gap-fill layer 100 may be formed using a deposition process to cover conformally surfaces of structures disposed on the cell array region CAR and the peripheral circuit region PERI. The insulating gap-fill layer 100 may be formed in a thickness greater than a difference in height between the top surfaces of the peripheral logic structure and the layered structure 110. In the case where the insulating gap-fill layer 100 is formed using a deposition process, there may be a height difference between the cell array region CAR and the peripheral circuit region PERI. In example embodiments, after the deposition of the insulating gap-fill layer 100, a planarization process may be performed to the insulating gap-fill layer 100 to reduce the height difference between the cell array region CAR and the peripheral circuit region PERI. As a result, the insulating gap-fill layer 100 may have a flat top surface.

The insulating gap-fill layer 100 may be formed of at least one of, for example, high density plasma (HDP) oxide, tetraethylorthosilicate (TEOS), plasma-enhanced TEOS, O3-TEOS, undoped silicate glass (USG), phosphosilicate glass (PSG), borosilicate glass (BSG), borophosphosilicate glass (BPSG), Fluoride Silicate Glass (FSG), spin on glass (SOG), tonen silazene (TOSZ), or any combination thereof. Further, the insulating gap-fill layer 100 may include at least one of silicon nitride, silicon oxynitride, or low-k materials.

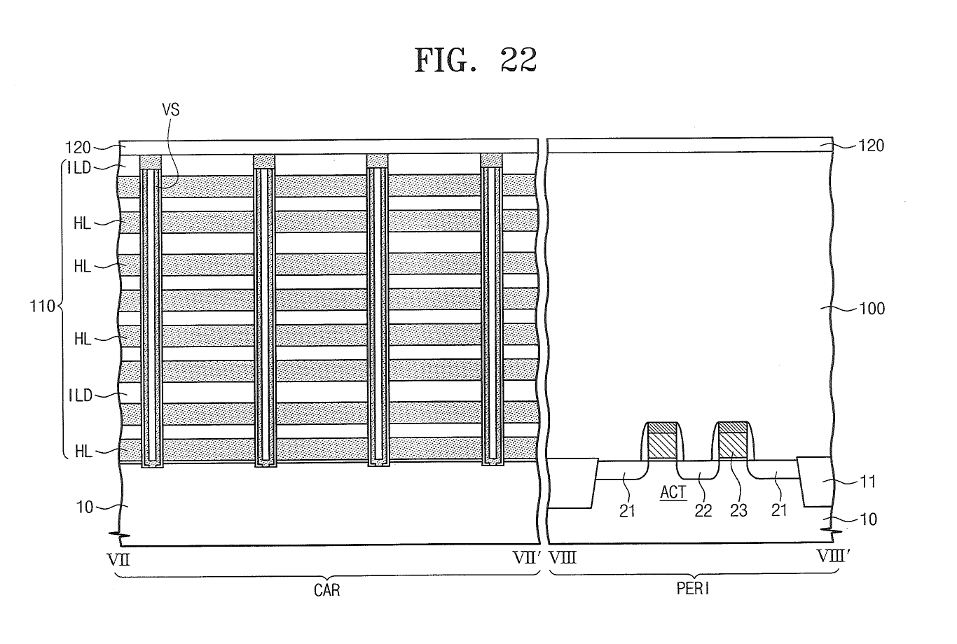

Referring to FIG. 22, the vertical structures VS and the data storing layer may be formed on the substrate 10 of the cell array region CAR to penetrate the layered structure 110. The vertical structures VS may include a semiconductor and/or conductive material.

In example embodiments, the formation of the vertical structures VS may include forming openings penetrating the layered structure 110, and forming semiconductor patterns in the openings, respectively.

The formation of the openings may include forming a mask pattern (not shown) on the layered structure 110, and then, anisotropically etching the layered structure 110 using the mask pattern as an etch mask. In certain embodiments, the top surface of the substrate 10 may be over-etched during the anisotropic etching process. For example, a portion of the top surface of the substrate 10 exposed by the openings may be recessed to have a specific depth. Further, when the anisotropic etching process is finished, the opening may have a bottom width smaller than a top width W thereof. When viewed in plan view, the openings may be arranged along a specific direction or in a zigzag manner.

In example embodiments, the formation of the semiconductor pattern in the opening may include forming a semiconductor spacer SP2 exposing a portion of the substrate 10 and covering sidewalls of the openings, and forming a semiconductor body portion SP1 connected to the semiconductor the substrate 10. The semiconductor pattern may include silicon (Si), germanium (Ge), or any mixture thereof and contain a doped or intrinsic semiconductor layer. Further, a crystal structure of the semiconductor pattern may be at least one of single crystalline, amorphous, and polycrystalline. The semiconductor pattern may have a pipe-shaped or macaroni-shaped structure. Here, the semiconductor pattern may be formed to have a closed bottom. In addition, a conductive pad may be provided on the vertical structure VS or in an upper portion of the vertical structure VS. The conductive pad may be a doped semiconductor pattern or a conductive pattern.

In example embodiments, a portion of the data storing layer may be formed before forming the vertical structures VS. For example, the vertical pattern VP of the data storing layer may be formed before forming the vertical structures VS. The vertical pattern VP may include one or more layers. In example embodiments, the vertical pattern VP may include a tunnel insulating layer for a cell transistor of a charge-trap type FLASH memory device. The tunnel insulating layer may include or be one of materials having a band gap higher than a charge storing layer. For example, the tunnel insulating layer may be high-k dielectrics (e.g., aluminum oxide and hafnium oxide). The vertical pattern VP may include a charge storing layer for the cell transistor of the charge-trap type FLASH memory device. The charge storing layer may include or be one of an insulating layer (e.g., silicon nitride) having many trap sites, a floating gate electrode, or an insulating layer having conductive nano dots.

Referring to FIG. 22, after the formation of the vertical structures VS, a capping dielectric 120 may be formed to cover top surfaces of the vertical structures VS and the layered structure 110. In certain embodiments, the capping dielectric 120 may extend and cover the insulating gap-fill layer 100 on the peripheral circuit region PERI.

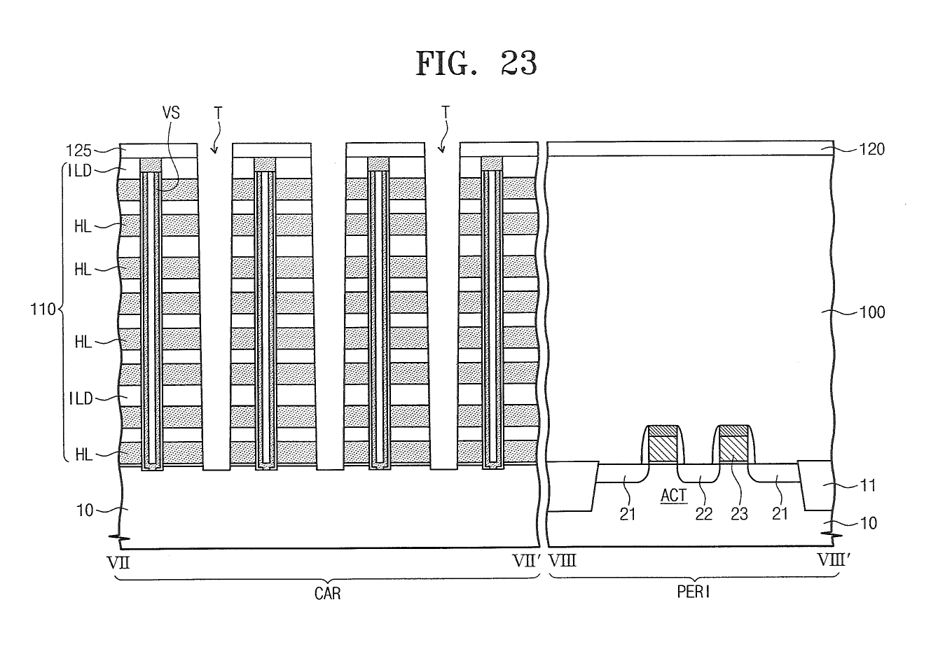

Referring to FIG. 23, the layered structure 110 may be patterned to form cell trenches T. The cell trenches T may be formed to expose the substrate 10 between the vertical structures VS disposed adjacent to each other.

For example, the formation of the cell trenches T may include forming a mask pattern (not shown) on the layered structure 110 to define positions of the cell trenches T, and then, anisotropically etching the layered structure 110 using the mask pattern (not shown) as an etch mask.

The cell trenches T may be formed spaced apart from the vertical structures VS and be formed to expose sidewalls of the sacrificial layers HL and the insulating layers ILD. When viewed in plan view, each of the cell trenches T may be shaped like a line or a rectangle. In terms of a vertical depth, the cell trenches T may be formed to expose the top surface of the substrate 10. In certain embodiments, the substrate 10 exposed by the cell trenches T may have a recessed top surface, when the formation of the cell trenches T is finished. Further, the cell trenches T may be formed to have a sidewall at an angle to the top surface of the substrate 10.

As a result of the formation of the cell trenches T, the layered structure 110 may have a plurality of line-shape portions extending along the first direction D1. Here, a plurality of the vertical structures VS may be formed to penetrate each of the line-shaped portions of the layered structure 110.

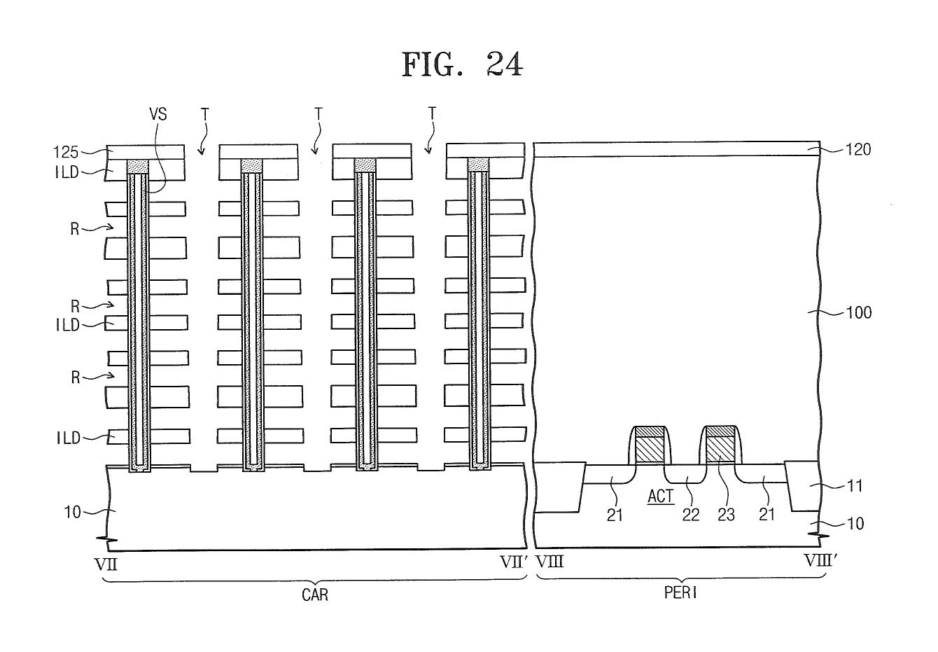

Referring to FIG. 24, the sacrificial layers HL exposed by the cell trenches T may be removed to form gate regions R between the insulating layers ILD.

In detail, the gate regions R may be formed by isotropically etching the sacrificial layers HL using an etch recipe having an etch selectivity with respect to the insulating layers ILD, the vertical structures VS and the substrate 10. The sacrificial layers HL may be completely removed by the isotropic etching process. For example, in the case where the sacrificial layers HL is a silicon nitride layer and the insulating layers ILD is a silicon oxide layer, the isotropic etching process may be performed using etching solution containing phosphoric acid.

The gate regions R may be horizontally extended from the cell trench T and be formed between the insulating layers ILD. Accordingly, a sidewall of the vertical insulating pattern or the vertical structure VS may be partially exposed by the gate regions R. For example, the gate regions R may be delimited by vertically adjacent ones of the insulating layers ILD and the sidewall of the vertical insulating pattern. Furthermore, the vertical insulating pattern may be used as an etch stop layer in the isotropic etching process for forming the gate regions R.

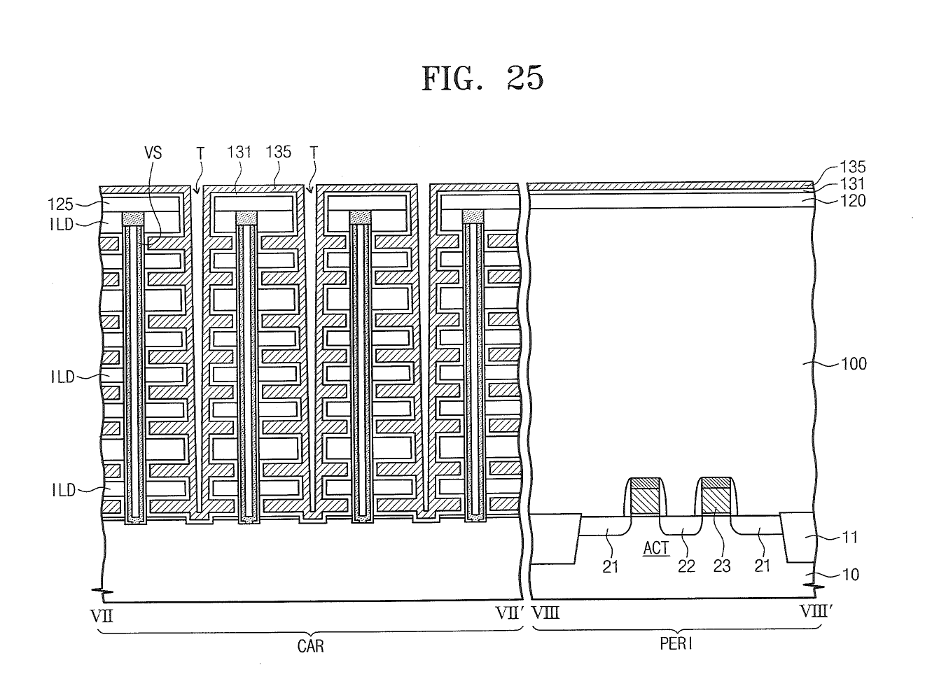

Referring to FIG. 25, a horizontal insulating layer 131 may be formed to cover conformally inner walls of the gate regions R.

The horizontal insulating layer 131 may be formed to have substantially a uniform thickness, on the inner walls of the gate regions R. In example embodiments, the horizontal insulating layer 131 may include a layer or a plurality of layers. In example embodiments, the horizontal insulating layer 131 may include a blocking insulating layer for the cell transistor of the charge-trap type FLASH memory device. The blocking insulating layer may include or be one of materials, whose band gaps are smaller than that of the tunnel insulating layer and larger than that of the charge storing layer. For example, the blocking insulating layer may be high-k dielectrics (e.g., aluminum oxide and hafnium oxide).

A gate conductive layer 135 may be formed to fill the gate regions R provided with the horizontal insulating layer 131. The gate conductive layer 135 may be formed to fill partially or fully the cell trench T. In example embodiments, the formation of the gate conductive layer 135 may include sequentially depositing a barrier metal layer and a metal layer. The barrier metal layer may include a metal nitride layer (e.g., of TiN, TaN or WN). The metal layer may include a metal layer (e.g., of W, Al, Ti, Ta, Co, or Cu).

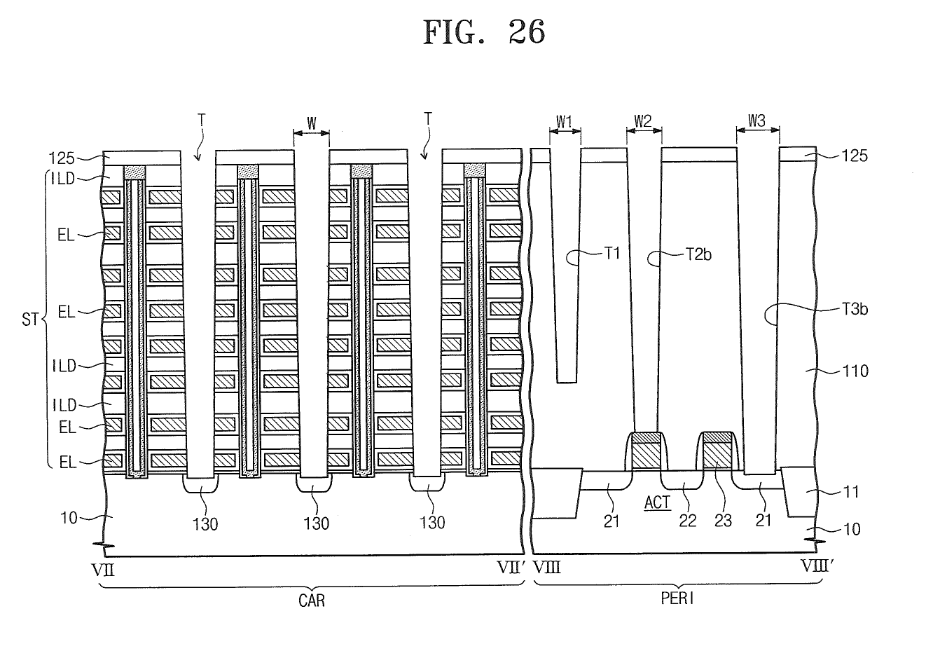

Referring to FIG. 26, the gate conductive layer may be removed from the cell trench T, and thus, electrodes EL may be locally formed in the gate regions R, respectively.

In example embodiments, the electrodes EL may be formed by anisotropically etching the gate conductive layer in the cell trench T. Alternatively, the electrodes EL may be formed by isotropically etching the gate conductive layer in the cell trenches T. When the gate conductive layer is removed from the cell trench T, the gate conductive layer may be removed from the peripheral circuit region PERI. After the formation of the electrodes EL, the horizontal insulating layer 131 exposed by the cell trench T may be partially removed to locally form horizontal insulating patterns in the gate regions R, and in this step, the horizontal insulating layer may be removed from the peripheral circuit region PERI.

Since the gate conductive layer is partially removed from the cell trench T, the stacks ST, in which the insulating layers ILD and the electrodes EL are alternately stacked one on another, may be formed on the cell array region CAR. The stacks ST may extend parallel to the first direction D1 and have the sidewalls exposed by the cell trenches T. The semiconductor the substrate 10 may be exposed between adjacent ones of the stacks ST.

In example embodiments, when the electrodes EL are formed on the cell array region CAR, the capping dielectric 120 and the insulating gap-fill layer 100 on the peripheral circuit region PERI may be patterned to form first to third trenches T1, T2a, T2b, T3a, and T3b. In other embodiments, the first to third trenches T1, T2a, T2b, T3a, and T3b may be formed before forming the recess regions on the cell array region CAR; for example, they may be formed using the process of forming the cell trenches T.

The formation of the first to third trenches T1, T2a, T2b, T3a, and T3b may include forming an etching mask pattern (not shown) on the capping dielectric 120, and then, anisotropically etching the capping dielectric 120 and the insulating gap-fill layer 100.

The first to third trenches T1, T2a, T2b, T3a, and T3b may be formed to have downward taper shape. Further, as a result of a micro loading effect in the anisotropic etching process, an etching depth of the insulating gap-fill layer 100 may be changed depending on a top width of an opening in the etching mask pattern. For example, the etching depth of the insulating gap-fill layer 100 may be changed depending on top widths of the first to third trenches T1, T2a, T2b, T3a, and T3b.

In example embodiments, the first trench T1 may extend parallel to the first direction D1 with a top width (e.g., the first top width W1) smaller than the top width W of the cell trench T. In this case, as a result of a micro loading effect in the process of forming the cell trench T and the first trench T1, an etching depth of the first trench T1 may be smaller than that of the cell trench T. Accordingly, the first trench T1 may have the bottom surface spaced apart from the top surface of the substrate 10. The first trench T1 may be formed to have a slanted sidewall, and in example embodiments, the bottom width of the first trench T1 may be smaller than about ½ of the top width W1.

When viewed in plan view, the second trench may be overlapped with peripheral word line 23 and extend parallel to the first direction D1. The second trench may include the first portions T2a and the second portion T2b between the first portions T2a. The first portions T2a may have a substantially uniform top width (e.g., the first top width W1), and the second portion T2b may have the second top width W2 larger than the first top width W1. In example embodiments, the first and second top widths W1 and W2 of the second trench may be smaller than the top width W of the cell trench T. Since the first portions T2a and the second portion T2b of the second trench have different top widths W1 and W2 from each other, there may be a difference in the micro loading effect between the first portions T2a and the second portion T2b, when the anisotropic etching process for forming the second trench is performed. Accordingly, when the cell trench T and the first trench T1 are formed using the same process, the etching depth of the second trench may be smaller in the first portions T2a than in the second portion T2b, as described with reference to FIG. 7. For example, the second portion T2b of the second trench may be formed to expose the top surface of the peripheral word line 23.

When viewed in plan view, the third trench may extend parallel to the first direction D1 and be partially overlapped with the source or drain impurity region 21 or 22. Similar to the second trench, the third trench may include the first portions T3a having substantially a uniform top width (e.g., the first top width W1) and the second portion T3b disposed between the first portions T3a to have a third top width W3 larger than the first top width W1. In example embodiments, the first top width W1 of the third trench may be smaller than the top width W of the cell trench T. The third top width W3 of the third trench may be greater than the top width W of the common source structure CSL.

Since the first and second portions T3a and T3b of the third trench have different top widths W1 and W3, the etching depth of the third trench may be larger in the second portion T3b than in the first portions T3a, as described with reference to FIG. 7. In certain embodiments, the first portions T3a of the third trench may have the bottom surface spaced apart from the top surface of the semiconductor the substrate 10, and the second portion T3b of the third trench may expose partially the source or drain impurity region 21 or 22.

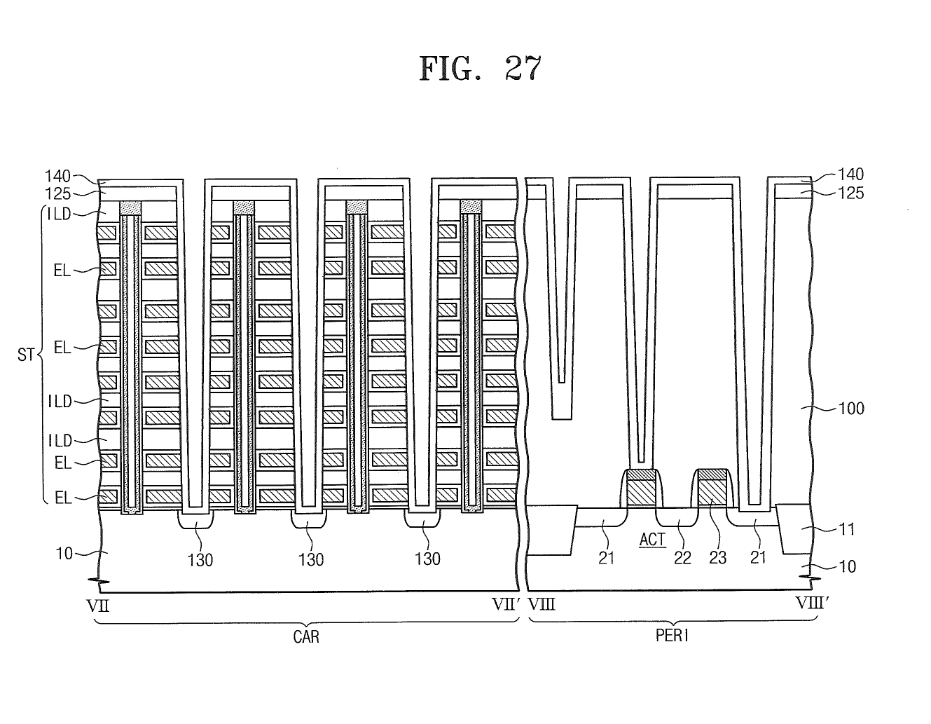

Referring to FIG. 27, a spacer layer 140 may be formed in the cell trench T and the first to third trenches T1, T2a, T2b, T3a, and T3b.

The spacer layer 140 may be formed of an insulating material and be deposited to have a thickness that is smaller than about ½ of the top width W1 of the first trench T1. For example, the spacer layer 140 may include at least one of silicon oxide, silicon nitride, silicon oxynitride, or low-k materials. The spacer layer 140 may be deposited using a deposition technique (e.g., CVD or ALD) capable of providing good step coverage property.

The spacer layer 140 may be conformally deposited on the top surface of the capping dielectric pattern 125 and the inner walls of the cell trench T and the first to third trenches T1, T2a, T2b, T3a, and T3b. In certain embodiments, in the case where the first trench T1 and the first portions T2a and T3a of the second and third trenches have bottom widths smaller than ½ of the top widths W1 thereof, the spacer layer 140 may be deposited thickly on the bottom surfaces of the first trench T1 and the first portions T2a and T3a of the second and third trenches, as described with reference to FIG. 8.

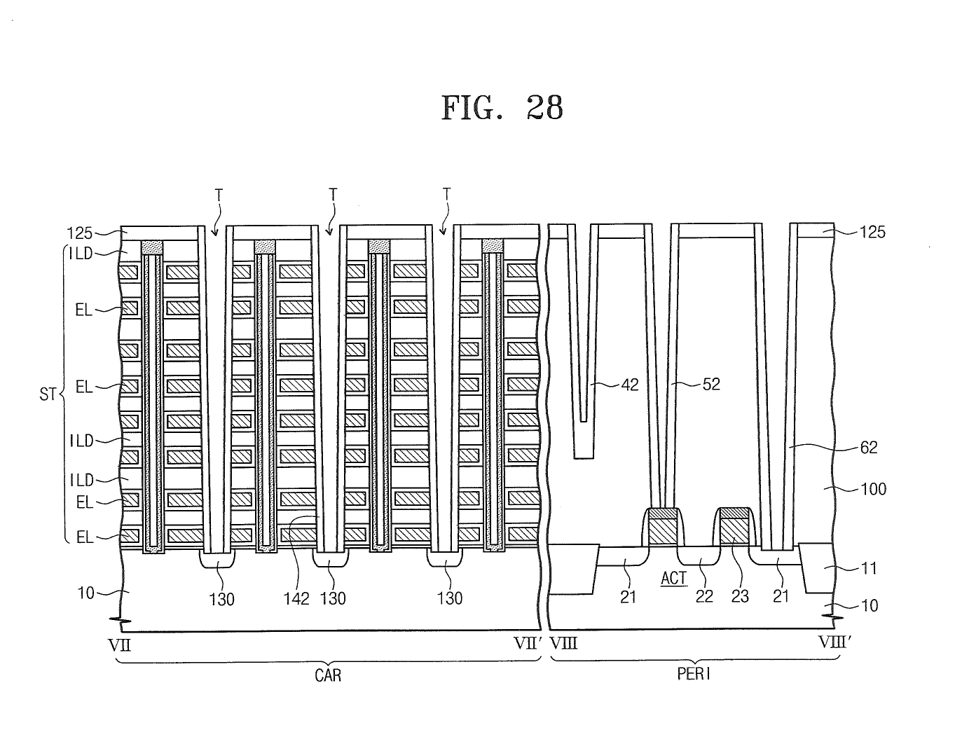

Referring to FIG. 28, the spacer layer 140 may be etched using an anisotropic blanket etching process (e.g., an etch-back process), and thereby, the insulating sidewall spacer 142, the first insulating spacer 42, the second insulating spacer 52, and the third insulating spacer 62 may be formed in the cell trench T, the first trench T1, the second trench, and the third trench, respectively.

In example embodiments, the etching process of the spacer layer 140 may be performed to expose the substrate 10 between the stacks ST. For example, the insulating sidewall spacer 142 may be formed to cover the sidewalls of the stacks ST and expose the substrate 10 between the stacks ST. Further, the spacer layer 140 may be removed from the bottom surfaces of the second portions T2b and T3b of the second and third trenches. Accordingly, the second portion T2b of the second trench may expose a portion of the top surface of the gate electrode, and the second portion T3b of the third trench may expose a portion of the top surface of the source or drain impurity region 21 or 22. Here, the spacer layer 140 may have a reduced thickness on the bottom surface of the first trench T1, and in certain embodiments, a portion of the spacer layer 140 may remain on the bottom surface of the first trench T1. Similarly, a portion of the spacer layer 140 may remain on the bottom surfaces of the first portions T2a and T3a of the second and third trenches.

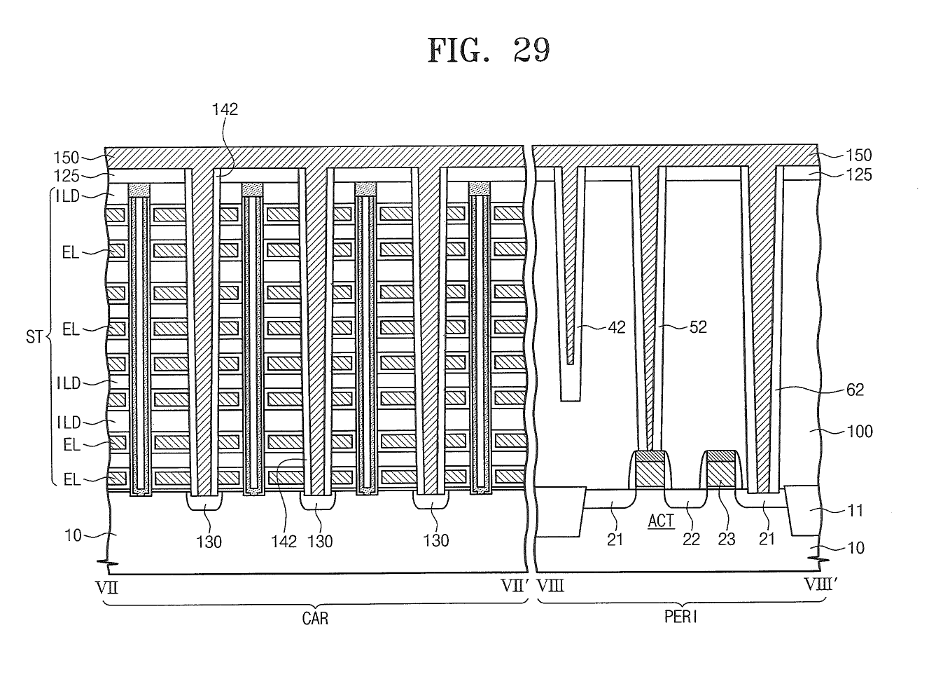

Referring to FIG. 29, a conductive layer 150 may be formed to fill the cell trench T and the first to third trenches T1, T2a, T2b, T3a, and T3b.

The conductive layer 150 may be formed of a metallic material (e.g., tungsten), and in this case, the formation of the conductive layer 150 may include sequentially forming a barrier metal layer (e.g., of metal nitride) and a metal layer (e.g., of tungsten). The conductive layer 150 may be formed using a deposition process (e.g., CVD or ALD).

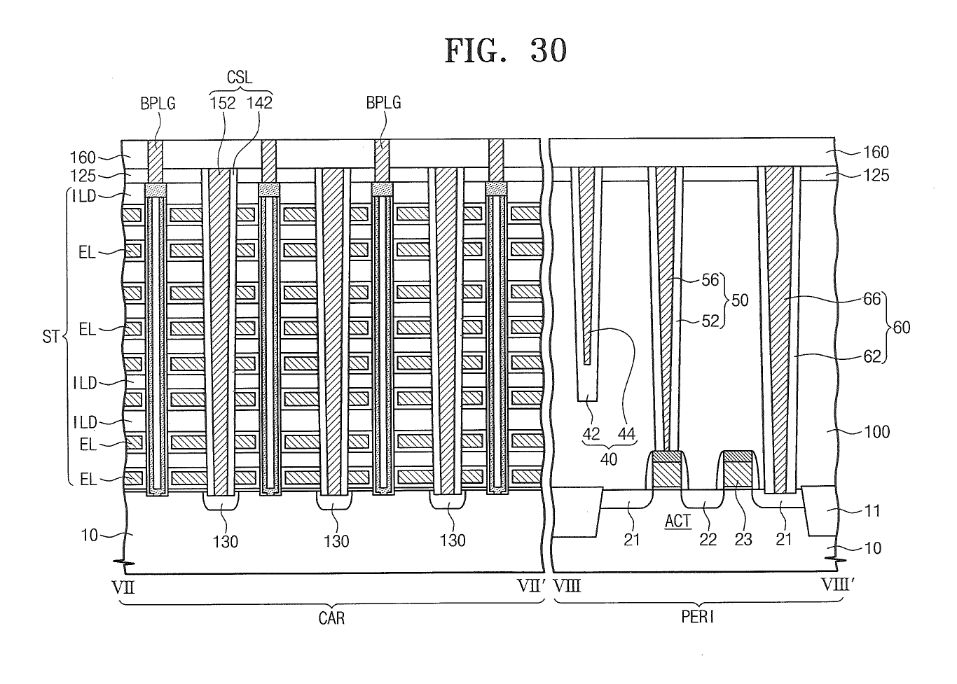

Referring to FIG. 30, a planarization process may be performed to the conductive layer 150 to expose the top surface of the capping dielectric pattern 125. Accordingly, the common source structure CSL and the first to third interconnection structures 40, 50, and 60 may be formed, and the common source structure CSL may have a top surface that is coplanar with top surfaces of the first to third interconnection structures 40, 50, and 60.

For example, as described with reference to FIGS. 15 and 16, the common source structure CSL including the insulating sidewall spacer 142 and the common source line 152 may be formed in the cell trench T, and the first interconnection structure 40 including the first insulating spacer 42 and the first wiring portion 44 may be formed in the first trench T1. The second interconnection structure 50 including the second insulating sidewall spacer 142, the second wiring portion 54, and the second contact portion 56 may be formed in the second trench, and the third interconnection structure 60 including the third insulating sidewall spacer 142, the third wiring portion 64, and the third contact portion 66 may be formed in the third trench.

The interlayered insulating layer 160 may be formed to cover the top surfaces of the common source structure CSL and the first to third interconnection structures 40, 50, and 60. The bit line plugs BPLG may be formed in the interlayered insulating layer 160 and be connected to the vertical structure VS of the cell array region CAR. Further, the first to third contact plugs (e.g., CP1, CP2, and CP3 in FIG. 15), may be connected to the first to third interconnection structures 40, 50, and 60 of the peripheral circuit region PERI.

Thereafter, as shown in FIG. 16, the upper interconnection lines ICL may be formed on the interlayered insulating layer 160 of the peripheral circuit region PERI. The upper interconnection lines ICL may extend parallel to the second direction crossing the first to third interconnection structures 40, 50, and 60. In example embodiments, at least two of the interconnection lines may be electrically connected to the first interconnection structure 40. Similarly, at least two of the interconnection lines may be electrically connected to the second or third interconnection structure 50 or 60.

According to example embodiments of the inventive concept, when the upper interconnection lines ICL are formed, the bit lines BL may be formed on the interlayered insulating layer 160 of the cell array region CAR and be connected to the bit line contact plugs BPLG.

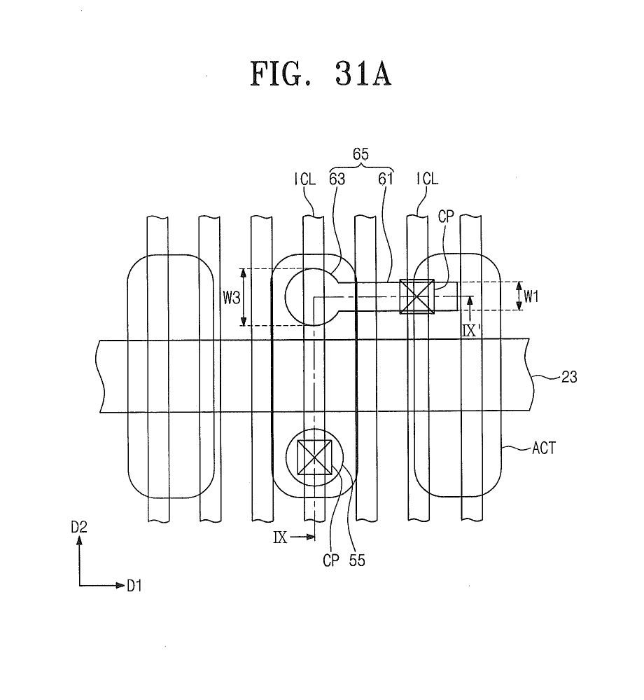

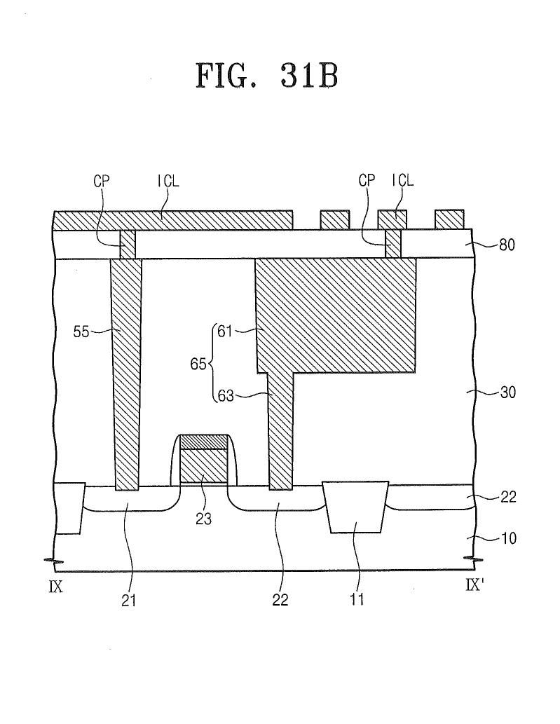

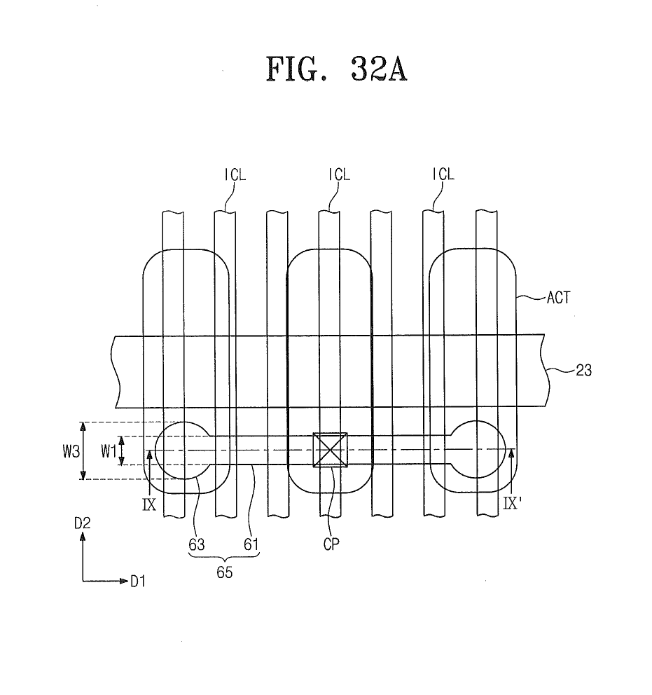

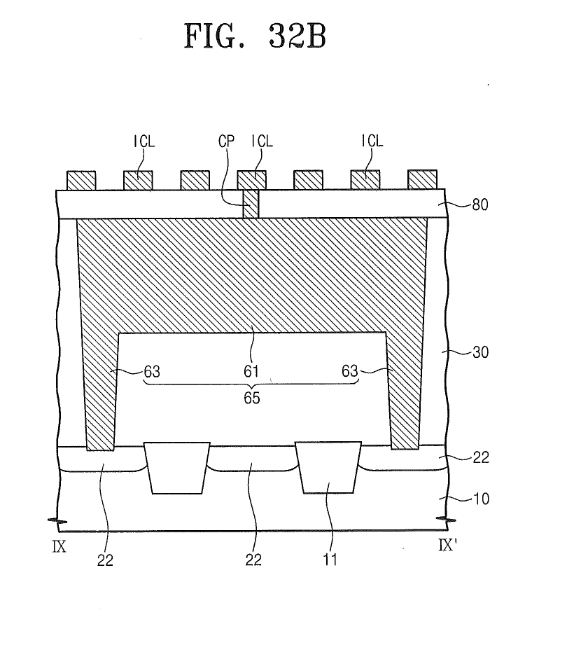

FIGS. 31A and 32A are plan views of semiconductor devices according to further embodiments of the inventive concept, and FIGS. 31B and 32B are sectional views taken along lines IX-IX′ of FIGS. 31A and 32A, respectively, to illustrate the semiconductor devices according to further embodiments of the inventive concept.

Referring to FIGS. 31A and 31B, the device isolation layer 11 may be provided on the semiconductor substrate 10 to define the active regions ACT. The gate electrodes 23 may be provided on the semiconductor substrate 10 with the gate insulating layer interposed therebetween. The gate electrodes 23 may extend to cross the active regions ACT (for example, parallel to the first direction D1). The source and drain impurity regions 21 and 22 may be formed in portions of the active regions ACT positioned at both sides of the gate electrodes 23. For example, the source and drain impurity regions 21 and 22 may be formed by an impurity doping process.

The first interlayered insulating layer 30 may be provided on the semiconductor substrate 10 to cover the gate electrodes 23. The first interlayered insulating layer 30 may include an insulating layer or a plurality of stacked insulating layers.

In example embodiments, a contact structure 55 and an interconnection structure 65 may be formed in the first interlayered insulating layer 30. The interconnection structure 65 may include a wiring portion 61 extending along the first direction D1 and a contact portion 63 connected to the drain impurity region 22. The wiring portion 61 may have a top width W1 that is smaller than an top width W3 of the contact portion 63. Further, the wiring portion 61 may have a vertical length that is smaller than that of the contact portion 63. In other words, a bottom surface of the wiring portion 61 may be positioned between the top surface of the first interlayered insulating layer 30 and the top surfaces of the gate electrodes 23. In the present embodiment, the contact portion 63 of the interconnection structure 65 may be provided at an end portion of the wiring portion 61. As described with reference to FIGS. 7 through 10, the wiring and contact portions 61 and 63 of the interconnection structure 65 may be formed by forming trenches, whose top widths are different from each other, in specific regions, and then, filling the trenches with a conductive material. Further, the interconnection structure 65 may further include insulating spacers (not shown) on sidewalls of the wiring and contact portions 61 and 63. In certain embodiments, the insulating spacers may be provided to cover a bottom surface of the wiring portion 61.

In example embodiments, the contact structure 55 may be connected to the source impurity region 21 through the first interlayered insulating layer 30. The contact structure 55 may be formed in such a way that a top surface thereof is coplanar with that of the interconnection structure 65.

The second interlayered insulating layer 80 may be disposed on the first interlayered insulating layer 30 to cover top surfaces of the contact structure 55 and the interconnection structure 65. A plurality of the upper interconnection lines ICL may be disposed on the second interlayered insulating layer 80 to extend along the second direction or to cross the gate electrodes 23. The upper interconnection lines ICL may be arranged in a uniform space, and a pitch of the upper interconnection lines ICL (that is, a sum of a line width of the upper interconnection line ICL and a space between two adjacent ones of the upper interconnection lines ICL) may be smaller than a width of the active region ACT. When viewed in plan view, the upper interconnection lines ICL may include portions overlapped with the active regions ACT.

At least one of the upper interconnection lines ICL may be electrically connected to the interconnection structure 65 via the contact plug CP. the contact plug CP may be connected to the wiring portion 61 of the interconnection structure 65 and may be spaced apart from the contact portion 63 of the interconnection structure 65, when viewed in plan view. Further, at least one of the upper interconnection lines ICL may be provided across the interconnection structure 65 but may be electrically separated from the interconnection structure 65. The upper interconnection lines ICL may be connected the interconnection structure 65, in consideration of positions of the contact plugs CP.

Referring to FIGS. 32A and 32B, the gate electrode 23 may be provided on the semiconductor substrate 10 to extend along the first direction D1 and cross the active regions ACT. The upper interconnection lines ICL may be disposed to cross the gate electrode 23, when viewed in plan view.

According to the present embodiment, when viewed in vertical section, the interconnection structure 65 may be provided between the active region ACT and the upper interconnection lines ICL. The interconnection structure 65 may include the wiring portion 61 extending along the first direction D1 and the contact portions 63 provided at end portions of the wiring portion 61. The wiring portion 61 may be provided to have a vertical length that is smaller than that of the contact portion 63. In addition, the wiring portion 61 may be provided to have a top width W1 that is smaller than a top width W3 of the contact portion 63. Each of the contact portions 63 may be connected to the drain impurity region 22 through the first interlayered insulating layer 30. In other words, the interconnection structure 65 may be connected in common to the drain impurity regions 22 spaced apart from each other.

The contact plug CP may be provided between the interconnection structure 65 and the upper interconnection lines ICL, when viewed in vertical section, and may be spaced apart from one of the contact portions 63 of the interconnection structure 65, when viewed in plan view. In other words, the contact plug CP may be provided in such a way that it is not overlapped with all of the contact portions 63, when viewed in plan view. At least one of the upper interconnection lines ICL may be electrically connected to the interconnection structure 65 via the contact plug CP.

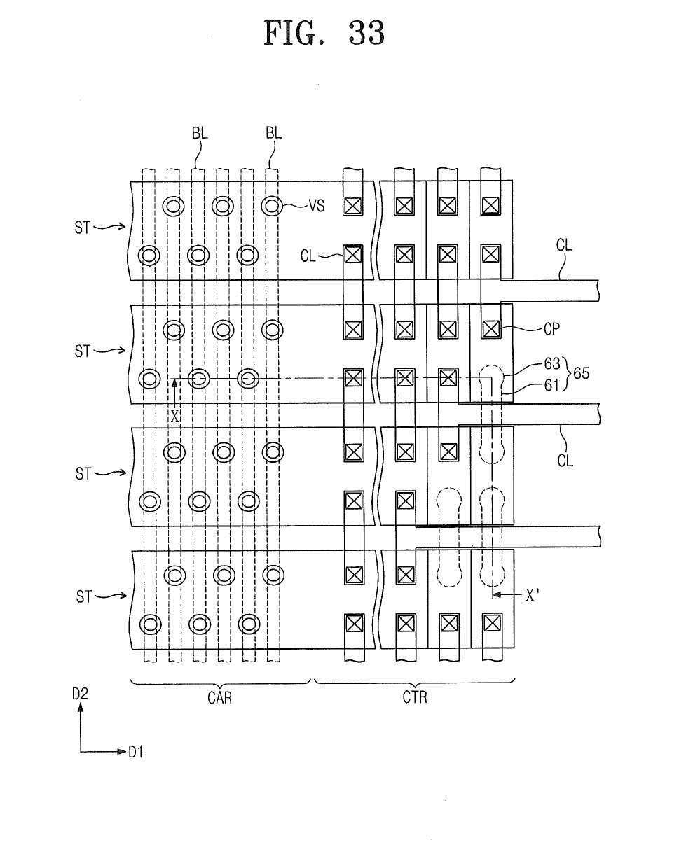

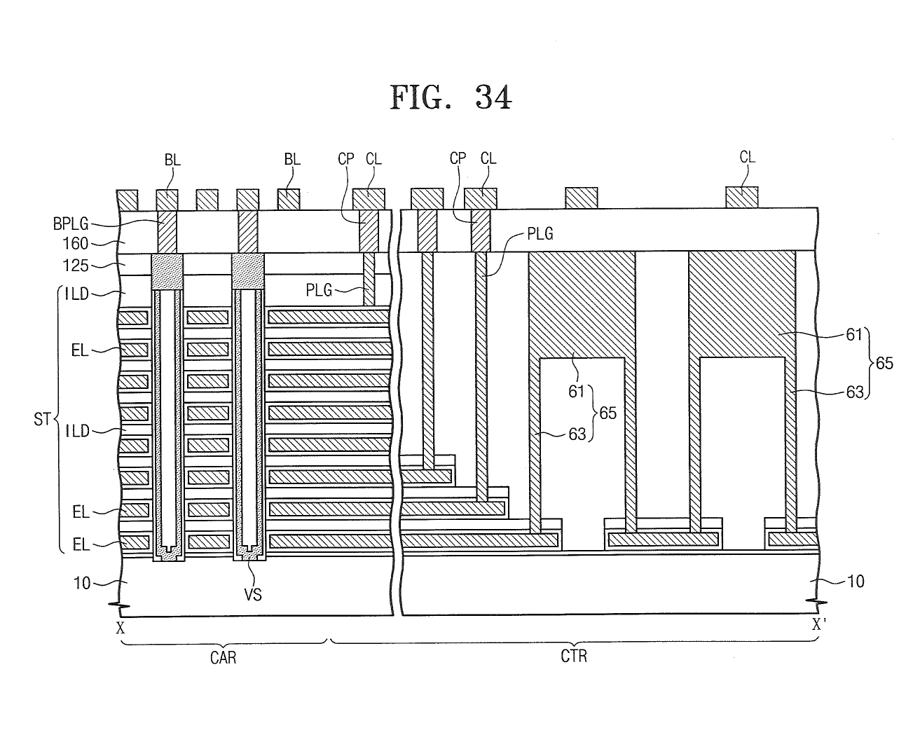

FIG. 33 is a plan view of a semiconductor memory device according to still further embodiments of the inventive concept, and FIG. 34 is a sectional view taken along line X-X′ of FIG. 33 to illustrate the semiconductor device according to still further embodiments of the inventive concept.

Referring to FIGS. 33 and 34, the substrate 10 may include the cell array region CAR and a contact region CTR provided around the cell array region CAR. a cell array structure may be provided on the substrate 10. The cell array structure may include a plurality of stacks ST and a plurality of vertical structures VS penetrating the stack ST, where each of the stacks ST may include electrodes EL and insulating layers ILD that are alternately stacked on the substrate 10. The stacks ST may be provided on the cell array region CAR and the contact region CTR, and the vertical structures VS may be provided on the cell array region CAR and be connected to the substrate 10. Further, the stacks ST may extend in the first direction D1 and be disposed spaced apart from each other in the second direction D2. Each of the vertical structures VS may include a semiconductor or conductive material. The vertical structures VS may be provided to have a zigzag arrangement in the first direction D1, when viewed in plan view.

Further, the stacks ST may be provided to have a stepwise structure on the contact region CTR. the electrodes EL may be electrically connected to a peripheral logic structure (not shown) through the stepwise structure of the stacks ST. In other words, on the contact region CTR, a vertical thickness of the stack ST may decrease stepwise in a direction away from the cell array region CAR. In other words, the stack ST may have a sloped profile, on the contact region CTR.

On the cell array structure, bit lines BL may be provided to cross the stacks ST or to extend along the second direction D2. The bit lines BL may be electrically connected to the vertical structures VS via the bit line contact plugs BPLG.

In example embodiments, a capping dielectric layer 125 may be provided on the substrate 10 to cover the cell array structure. The capping dielectric layer 125 may have a flat top surface and cover the stepwise edge portion of the stack ST. plugs PLG may be provided on the contact region CTR to penetrate the capping dielectric layer 125 and be connected to the electrodes EL1. Further, the interlayered insulating layer 160 may be provided on the insulating gap-fill layer 125, and the contact plugs CP may be connected to the plugs PLG, respectively, through the interlayered insulating layer 160. Connection lines CL may be provided on the interlayered insulating layer 160 to connect electrically ones of the electrodes EL disposed horizontally adjacent to each other. The connection lines CL may be connected to the contact plugs CP. some of the connection lines CL may extend toward the peripheral circuit region. In example embodiments, at least one of the connection lines CL may be disposed to cross the wiring portion 61 of the interconnection structure 60.

In example embodiments, the interconnection structure 65 may be provided in the capping dielectric layer 125 of the contact region CTR. The interconnection structure 65 may electrically connect the electrodes EL, which are positioned at the same level from the top surface of the substrate 10 and are disposed adjacent to each other in the second direction D2. For example, the interconnection structure 65 may include the wiring portion 61 extending in the second direction D2 and the contact portions 63 extending from the bottom surface of the wiring portion 61 and being connected to the electrodes EL. Here, the contact portions 63 may be disposed at the same level from the top surface of the substrate 10 and be connected to the electrodes EL that are positioned adjacent to each other in the second direction D2. In certain embodiments, the top surface of the wiring portion 61 may be coplanar with that of the insulating gap-fill layer 125. Further, the top width of the wiring portion 61 may be smaller than that of the contact portion 63, and a vertical length of the wiring portion 61 may be smaller than that of the contact portion 63.

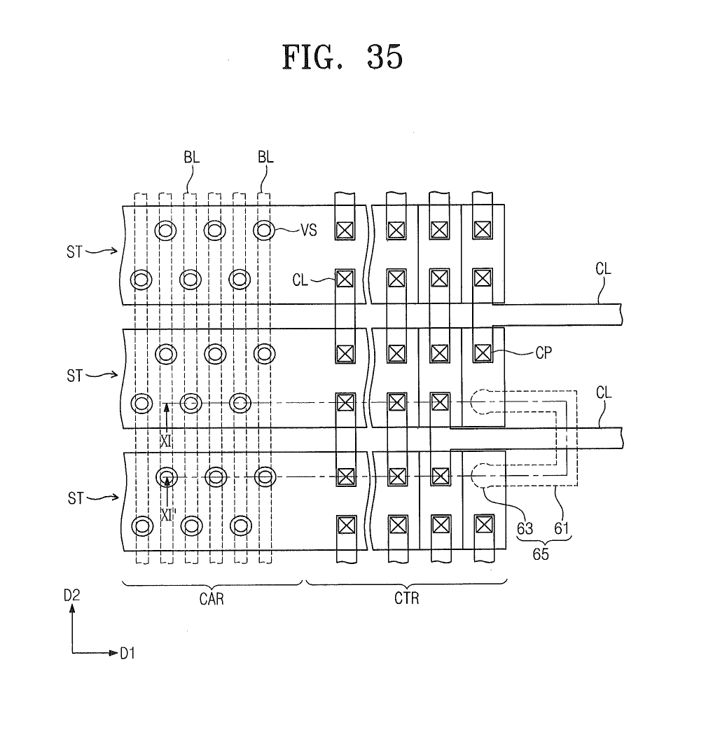

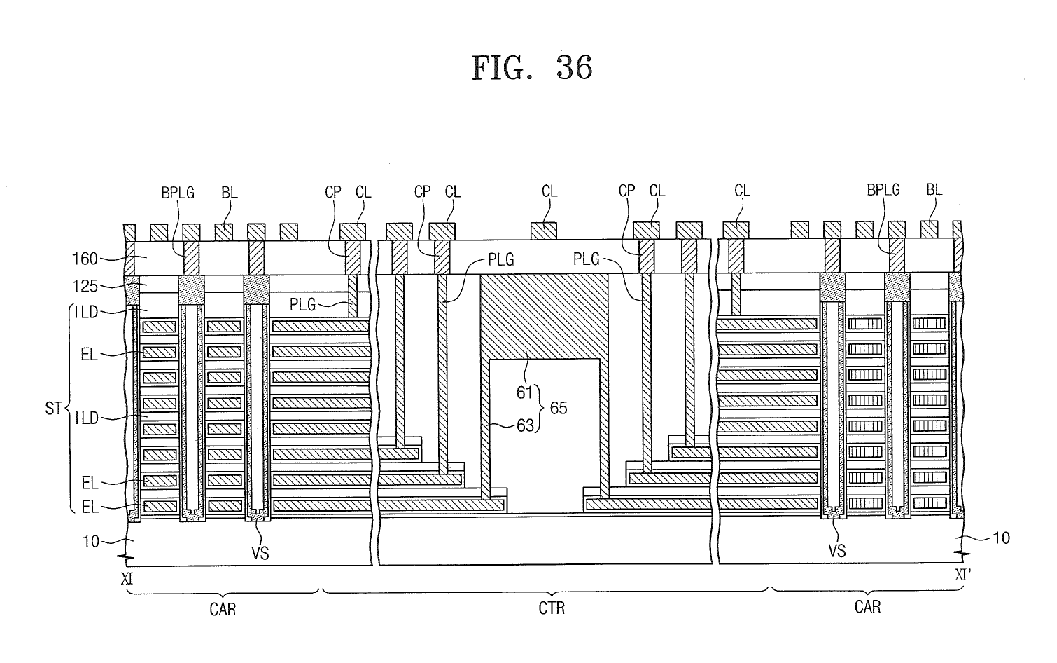

FIG. 35 is a plan view of a semiconductor memory device according to even further embodiments of the inventive concept, and FIG. 36 is a sectional view taken along line XI-XI′ of FIG. 35 to illustrate the semiconductor device according to even further embodiments of the inventive concept. In the following description of FIGS. 35 and 36, a previously described element may be identified by a similar or identical reference number without repeating an overlapping description thereof, for the sake of brevity.

Referring to FIG. 35 and FIG. 36, the interconnection structure 65 may be provided in the capping dielectric layer 125 of the contact region CTR. As described above, the interconnection structure 65 may include the wiring portion 61 and the contact portions 63. In the present embodiment, the wiring portion 61 may include first portions extending from the contact portions 63 along the first direction D1 and a second portion extending along the second direction D2 and being connected to the first portions. Further, some of the connection lines CL may be provided to cross the wiring portion 61 of the interconnection structure 60.

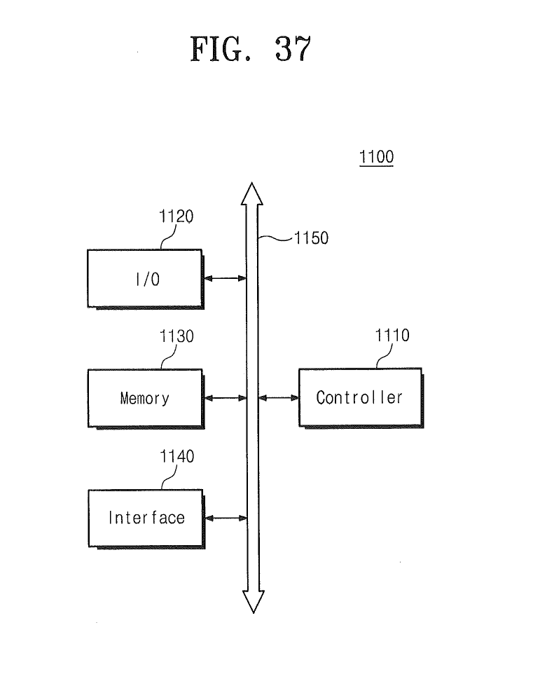

FIG. 37 is a block diagram illustrating an example of a memory system including a semiconductor memory device according to some embodiments of the inventive subject matter.

Referring to FIG. 37, a memory system 1100 can be applied to a PDA (personal digital assistant), a portable computer, a web tablet, a wireless phone, a mobile phone, a digital music player, a memory card and/or all the devices that can transmit and/or receive data in a wireless communication environment.

The memory system 1100 includes a controller 1110, an input/output device 1120 such as a keypad and a display device, a memory 1130, an interface 1140 and a bus 1150. The memory 1130 and the interface 1140 communicate with each other through the bus 1150.

The controller 1110 includes at least one microprocessor, at least one digital signal processor, at least one micro controller or other process devices similar to the microprocessor, the digital signal processor and the micro controller. The memory 1130 may be used to store an instruction executed by the controller 1110. The input/output device 1120 can receive data or a signal from the outside of the system 1100 or transmit data or a signal to the outside of the system 1100. For example, the input/output device 1120 may include a keyboard, a keypad and/or a displayer.

The memory 1130 includes the nonvolatile memory device according to embodiments of the inventive subject matter. The memory 1130 may further include a different kind of memory, a volatile memory device capable of random access and various kinds of memories.

The interface 1140 transmits data to a communication network or receives data from a communication network.

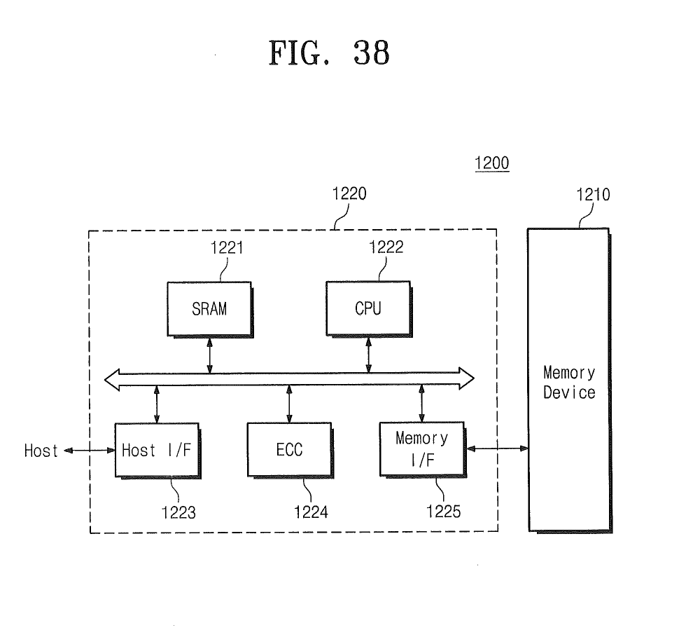

FIG. 38 is a block diagram illustrating an example of a memory card including a semiconductor memory device according to some embodiments of the inventive subject matter.

Referring to FIG. 38, the memory card 1200 for supporting a storage capability of a large capacity is fitted with a flash memory device 1210 according to some embodiments of the inventive subject matter. The memory card 1200 according to some embodiments of the inventive subject matter includes a memory controller 1220 controlling every data exchange between a host and the flash memory device 1210.

A static random access memory SRAM 1221 is used as an operation memory of a processing unit 1222. A host interface 1223 includes data exchange protocols of a host to be connected to the memory card 1200. An error correction block 1224 detects and corrects errors included in data readout from a multi bit flash memory device 1210. A memory interface 1225 interfaces with the flash memory device 1210 of some embodiments of the inventive subject matter. The processing unit 1222 performs every control operation for exchanging data of the memory controller 1220. Though not depicted in drawings, it will be apparent to one of ordinary skill in the art that the memory card 1200 according to some embodiments of the inventive subject matter can further include a ROM (not shown) storing code data for interfacing with the host.

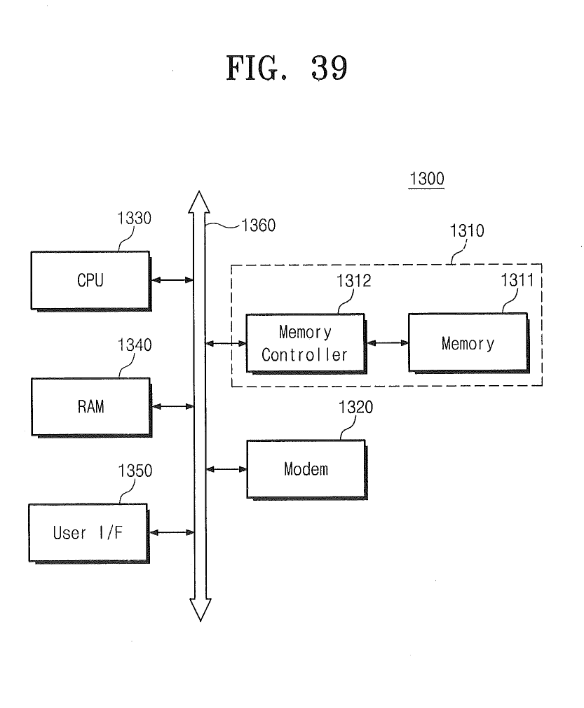

FIG. 39 is a block diagram illustrating an example of an information processing system including a semiconductor memory device according to some embodiments of the inventive subject matter.

Referring to FIG. 39, a memory system 1310 is built in a data processing system such as a mobile product or a desk top computer. The data processing system 1300 according to the inventive subject matter includes the memory system 1310 and a modem 1320, a central processing unit 1330, a RAM, a user interface 1350 that are electrically connected to a system bus 1360. The memory system 1310 may be constructed so as to be identical to the memory system described above. The memory system 1310 stores data processed by the central processing unit 1330 or data inputted from an external device. The memory system 1310 may include a SSD (solid state disk) and in this case, the data processing system 1310 can stably store huge amounts of data in the memory system 1310. As reliability is improved, the memory system 1310 can reduce resources used to correct errors, thereby providing a high speed data exchange function to the data processing system 1300. Even though not depicted in the drawings, it is apparent to one of ordinary skill in the art that the data processing unit 1300 according to some embodiments of the inventive subject matter can further include an application chipset, a camera image processor CIS and/or an input/output device.

Memory devices or memory systems utilizing the inventive concepts can be mounted using any of various types of packages. For example, a memory device or a memory system according to the inventive subject matter can be packaged with methods such as PoP (package on package), ball grid array BGA, chip scale package CSP, plastic leaded chip carrier PLCC, plastic dual in-line package PDIP, die in waffle pack, die in wafer form, chip on board COB, ceramic dual in-line package CERDIP, plastic metric quad flat pack MQFP, thin quad flat pack TQFP, small outline SOIC, shrink small outline package SSOP, thin small outline TSOP, system in package SIP, multichip package MCP, wafer-level fabricated package WFP, wafer-level processed stack package WSP and mounted.

According to example embodiments of the inventive concept, a plurality of interconnection lines may be provided to extend along a direction on a semiconductor substrate, and an interconnection structure may be provided between the interconnection lines and the semiconductor substrate to cross the interconnection lines. The interconnection structure may connect separated ones of the interconnection lines electrically to each other. Further, the interconnection structure may include a wiring portion extending along a direction and a contact portion connected to peripheral logic devices. Accordingly, it is easy to connect separated ones of the interconnection lines electrically to the peripheral logic devices.

Further, the wiring portion of the interconnection structure may be spaced apart from a top surface of a peripheral circuit region of the semiconductor substrate and be simultaneously formed with a common source structure, which may penetrate the stacks in the cell array region and be connected to the semiconductor substrate.

While example embodiments of the inventive concepts have been particularly shown and described, it will be understood by one of ordinary skill in the art that variations in form and detail may be made therein without departing from the spirit and scope of the attached claims.

What is claimed is:

1. An integrated circuit memory device, comprising:
a plurality of stacks of a first height on a cell array region of a substrate, said substrate having the cell array region and a peripheral circuit region therein;
a common source structure extending between adjacent ones of said plurality of stacks;
a logic structure of a second height less than the first height, extending on the peripheral circuit region of the substrate;
a plurality of upper interconnection lines extending on said logic structure; and
an interconnection structure extending between said logic structure and said plurality of upper interconnection lines and electrically coupled to at least two of said plurality of upper interconnection lines, said interconnection structure having a top surface positioned between a top surface of said common source structure and bottom surfaces of said plurality of upper interconnection lines.

2. The memory device of claim 1, wherein a bottom surface of said interconnection structure is positioned between top and bottom surfaces of said common source structure; and wherein a top width of said interconnection structure is smaller than a width of said common source structure.

3. The memory device of claim 1, wherein said interconnection structure includes a first portion having a first top width smaller than a top width of said common source structure and a second portion having a second top width greater than a top width of said common source structure.

4. The memory device of claim 3, wherein a vertical length of the first portion of said interconnection structure is smaller than a vertical length of the second portion of said interconnection structure.

5. The memory device of claim 1, wherein said interconnection structure comprises:
a wiring portion on the peripheral circuit region, said wiring portion having a bottom surface spaced apart from a top surface of the substrate and a side surface disposed at a non-orthogonal angle relative to the top surface of the substrate; and
an insulating spacer enclosing the side and bottom surfaces of the wiring portion.

6. A semiconductor device, comprising:
a substrate including a cell array region and a peripheral circuit region; stacks on the cell array region of the substrate, the stacks having a first height and extending along a direction;
a common source structure disposed between adjacent ones of the stacks;
a peripheral logic structure disposed on the peripheral circuit region of the substrate and having a second height smaller than the first height;
a plurality of upper interconnection lines disposed on the peripheral logic structure and extending parallel to each other; and
a interconnection structure disposed between the peripheral logic structure and the upper interconnection lines, when viewed in vertical section, and electrically connected to at least two of the upper interconnection lines,
wherein a top surface of the interconnection structure is positioned between a top surface of the common source structure and bottom surfaces of the upper interconnection lines, when viewed in vertical section.

7. The semiconductor device of claim 6, wherein a bottom surface of the interconnection structure is positioned between the top and bottom surfaces of the common source structure and a top width of the interconnection structure is smaller than that of the common source structure.

8. The semiconductor device of claim 6, wherein the interconnection structure comprises a first portion having a first top width smaller than a top width of the common source structure and a second portion having a second top width greater than the top width of the common source structure.

9. The semiconductor device of claim 8, wherein the first portion has a vertical length smaller than a vertical length of the second portion.

10. The semiconductor device of claim 6, wherein the interconnection structure comprises:
a wiring portion having a bottom surface spaced apart from a top surface of the substrate and a side surface at an angle to the top surface of the substrate, on the peripheral circuit region; and
an insulating spacer enclosing the side and bottom surfaces of the wiring portion.

11. The semiconductor device of claim 10, wherein a thickness of the insulating spacer is thicker on the bottom surface of the wiring portion than the side surface of the wiring portion.

12. The semiconductor device of claim 6, wherein the interconnection structure comprises:
a wiring portion having a uniform first top width and having a bottom surface spaced apart from a top surface of the substrate and a side surface at an angle to the top surface of the substrate, on the peripheral circuit region;
a contact portion having a second top width greater than the first top width of the wiring portion and a vertical length greater than a vertical length of the wiring portion; and
an insulating spacer covering side surfaces of the wiring and contact portions and extending to the bottom surface of the wiring portion.

13. The semiconductor device of claim 12, wherein the bottom surface of the wiring portion of the interconnection structure is spaced apart from the peripheral logic structure and the contact portion of the interconnection structure is electrically connected to the peripheral logic structure.

14. The semiconductor device of claim 6, further comprising a common source region formed in the substrate between adjacent ones of the stacks,
wherein the common source structure comprises an insulating sidewall spacer covering side surfaces of the stacks and a common source line penetrating the insulating sidewall spacer to be connected to the common source region.

15. A method of fabricating a semiconductor device, comprising:
providing a substrate with a cell array region and a peripheral circuit region;
forming a plurality of stacks on the cell array region of the substrate, the stacks extending along a direction and defining a cell trench exposing the substrate;
forming an insulating gap-fill layer on the peripheral circuit region of the substrate to include a first peripheral trench, whose bottom surface is spaced apart from a top surface of the substrate and whose top width is smaller than a top width of the cell trench;
forming an insulating sidewall spacer in the cell trench and a first insulating spacer in the first peripheral trench, the insulating sidewall spacer exposing the substrate and the first insulating spacer covering side and bottom surfaces of the first peripheral trench; and
forming a common source line filling the cell trench provided with the insulating sidewall spacer and a conductive line filling the first peripheral trench provided with the first insulating spacer.

16. The method of claim 15, wherein the insulating gap-fill layer is formed to further include a second peripheral trench extending parallel to the first peripheral trench, and
the second peripheral trench comprises a first portion having a first top width smaller than the top width of the cell trench and a second portion having a second top width greater than the top width of the cell trench.

17. The method of claim 16, wherein, in the second peripheral trench, the first portion is formed to have a bottom surface spaced apart from the top surface of the substrate and the second portion is formed to expose the substrate.

18. The method of claim 16, wherein the forming of the first insulating spacer further comprises forming a second insulating spacer covering an inner wall of the second peripheral trench and expose the substrate.

19. The method of claim 15, wherein the forming of the insulating sidewall spacer and the first insulating spacer comprises:
forming an insulating spacer layer to cover side and bottom surfaces of the cell trench and the first peripheral trench, a thickness of the insulating spacer layer being thicker on the bottom surface of the first peripheral trench than on the side surface of the first peripheral trench; and
performing an etch-back process to the insulating spacer layer to remove a portion of the insulating spacer layer from the bottom surface of the cell trench.

20. The method of claim 15, further comprising forming upper interconnection lines on the peripheral circuit region to cross the conductive line, after the forming of the common source line and the conductive line,
wherein at least two of the upper interconnection lines are electrically connected to the conductive line.
